(19) United States
(12) Patent Application Publication
(10) Pub. No.: US 2019/0204736 A1
(43) Pub. Date: Jul. 4, 2019

(54) ACTINIC RAY-SENSITIVE OR RADIATION-SENSITIVE RESIN COMPOSITION, RESIST FILM, PATTERN FORMING METHOD, METHOD FOR MANUFACTURING ELECTRONIC DEVICE

(71) Applicant: FUJIFILM Corporation, Tokyo (JP)

(72) Inventors: Kazuhiro MARUMO, Shizuoka (JP); Naohiro TANGO, Shizuoka (JP)

(73) Assignee: FUJIFILM Corporation, Tokyo (JP)

(21) Appl. No.: 16/298,459

(22) Filed: Mar. 11, 2019

Related U.S. Application Data
(63) Continuation of application No. PCT/JP2017/030173, filed on Aug. 23, 2017.

(30) Foreign Application Priority Data
Oct. 4, 2016 (JP) 2016-196521

(51) Int. Cl. G03F 7/039; G03F 7/004; G03F 7/20

(52) U.S. Cl. CPC G03F 7/039; G03F 7/2002; G03F 7/2041; G03F 7/0045

(57) ABSTRACT

An actinic ray-sensitive or radiation-sensitive resin composition is an actinic ray-sensitive or radiation-sensitive resin composition including a resin A whose solubility in an alkali developer increases by the action of an acid, a compound B that generates an acid upon irradiation with actinic rays or radiation, a resin C that has a surface energy of more than 25 mJ/m² and has at least one of a fluorine atom or a silicon atom and a polarity conversion group, and a resin D that has a surface energy of 25 mJ/m² or less, in which the content of the resin D is 1.1% by mass or more with respect to the total solid content of the actinic ray-sensitive or radiation-sensitive resin composition.

### CROSS-REFERENCE TO RELATED APPLICATIONS

This application is a Continuation of PCT International Application No. PCT/JP2017/030173, filed on Aug. 23, 2017, which claims priority under 35 U.S.C. § 119(a) to Japanese Patent Application No. 2016-196521, filed on Oct. 4, 2016. Each of the above application(s) is hereby expressly incorporated by reference, in its entirety, into the present application.

### BACKGROUND OF THE INVENTION

### 1. Field of the Invention

The present invention relates to an actinic ray-sensitive or radiation-sensitive resin composition, a resist film, a pattern forming method, and a method for manufacturing an electronic device.

### 2. Description of the Related Art

In accordance with the miniaturization of various electronic device structures, liquid immersion exposure has been used in order to form finer resist patterns (hereinafter also simply referred to as “patterns”). In the liquid immersion exposure, pure water is used as an immersion liquid many cases.

In a case where exposure is performed using a scan-type liquid immersion exposure machine in the liquid immersion exposure, an immersion liquid is required to move at a high speed, following the movement of a lens in the liquid immersion exposure machine at a high speed.

JP2010-044358A discloses an actinic ray-sensitive or radiation-sensitive resin composition capable of forming a resist film (actinic ray-sensitive or radiation-sensitive resin composition film), in which an immersion liquid can move at a high speed.

### SUMMARY OF THE INVENTION

However, there has been a demand for further high-speed scanning in liquid immersion exposure in recent years.

The present inventors have performed liquid immersion exposure (immersion liquid: water) using the actinic ray-sensitive or radiation-sensitive resin composition described in JP2010-044358A, and have thus found that there is room for an improvement of water repellency of a resist film thus formed.

Furthermore, in a case where a pattern is formed using an actinic ray-sensitive or radiation-sensitive resin composition, a developing treatment using an alkali developer and a rinsing treatment with a rinsing liquid are carried out in many cases after an exposing treatment. In this regard, a hydrophilic solution such as an alkali developer and a rinsing liquid has been required to have wetting extendability on a resist film. That is, after the alkali developer and the resist film are in contact with each other, the resist film has been required to have high hydrophilicity.

In addition, uniformity in the line width of a pattern thus formed is also required. In other words, it is also required that a pattern having good line width roughness (LWR) can be formed.

The present invention has been made in consideration of the situation and has an object to provide an actinic ray-sensitive or radiation-sensitive resin composition which is capable of forming a resist film having excellent water repellency as well as improved hydrophilicity after being in contact with an alkali developer, and is capable of forming a pattern having excellent LWR.

Furthermore, the present invention has another object to provide a resist film, a pattern forming method, and a method for manufacturing an electronic device.

The present inventors have conducted extensive studies in order to accomplish the objects, and as a result, they have found that the objects can be accomplished by using a predetermined resin, thereby completion of the present invention.

That is, the present inventors have found that the objects can be accomplished by the following configurations.

(1) An actinic ray-sensitive or radiation-sensitive resin composition comprising:

a resin A whose solubility in an alkali developer increases by the action of an acid;

a compound B that generates an acid upon irradiation with actinic rays or radiation;

a resin C that has a surface energy of more than 25 mJ/m², has at least one of a fluorine atom or a silicon atom, and has a polarity conversion group; and

a resin D that has a surface energy of 25 mJ/m² or less,

in which a content of the resin D is 1.1% by mass or more with respect to the total solid content of the actinic ray-sensitive or radiation-sensitive resin composition.

(2) The actinic ray-sensitive or radiation-sensitive resin composition as described in (1), further comprising two or more solvents,

in which a boiling point of at least one solvent of the solvents is 140° C. or higher.

(3) The actinic ray-sensitive or radiation-sensitive resin composition as described in (2), comprising a first solvent having a boiling point of 140° C. or higher and a second solvent having a higher boiling point than the first solvent.

(4) The actinic ray-sensitive or radiation-sensitive resin composition as described in any one of (1) to (3),

in which a mass ratio of the resin D to the resin C is 0.1 or more.

(5) A resist film formed using the actinic ray-sensitive or radiation-sensitive resin composition as described in any one of (1) to (4).

(6) A pattern forming method comprising:

forming a resist film on a substrate using the actinic ray-sensitive or radiation-sensitive resin composition as described in any one of (1) to (4);

irradiating the resist film with actinic rays or radiation; and

developing the resist film irradiated with actinic rays or radiation using an alkali developer.

(7) A method for manufacturing an electronic device, comprising the pattern forming method as described in (6).

According to the present invention, it is possible to provide an actinic ray-sensitive or radiation-sensitive resin composition which is capable of forming a resist film having excellent water repellency as well as improved hydrophilicity after being in contact with an alkali developer, and is capable of forming a pattern having excellent LWR.

In addition, according to the present invention, it is possible to provide a resist film, a pattern forming method, and a method for manufacturing an electronic device.

### DESCRIPTION OF THE PREFERRED EMBODIMENTS

Hereinafter, the present invention will be described in detail.

Description of configuration requirements described below may be made on the basis of representative embodiments of the present invention in some cases, but the present invention is not limited to such embodiments.

Moreover, in the present specification, a numerical range expressed using “to” means a range that includes the preceding and succeeding numerical values of “to” as the lower limit value and the upper limit value, respectively.

Furthermore, “actinic rays” or “radiation” in the present specification means, for example, far ultraviolet rays typified by a bright line spectrum of a mercury lamp and an excimer laser, extreme ultraviolet lithography rays (EUV rays), X-rays, electron beams, or the like. Furthermore, in the present specification, light means actinic rays and radiation. In the present specification, “exposure” encompasses, unless otherwise specified, not only exposure by far ultraviolet rays typified by a bright line spectrum of a mercury lamp and an excimer laser, extreme ultraviolet rays. X-rays, EUV rays, or the like, but also writing by particle rays such as electron beams and ion beams.

Incidentally, in the present specification, “(meth)acrylate” represents acrylate and methacrylate.

The actinic ray-sensitive or radiation-sensitive resin composition of an embodiment of the present invention (hereinafter also referred to as “the composition of an embodiment of the present invention”) may include a combined use of a resin D exhibiting a predetermined surface energy and a resin C having a polarity conversion group, in which the resin D is used in a predetermined amount or more. By using the resin D in a predetermined amount or more, the water repellency of the resist film and the LWR of the pattern are excellent. In addition, by using the resin C, the hydrophilicity of the resist film after being in contact with the alkali developer is improved.

Hereinafter, the respective components included in the composition of the embodiment of the present invention will be first described, and then the pattern forming method will be described.

In addition, the resin C and the resin D which may be included in the present invention will be hereinafter described.

<Resin C that has Surface Energy of More than 25 mJ/m² and has at Least One of Fluorine Atom or Silicon Atom and Polarity Conversion Group>

The resin C is a resin which has a surface energy of more than 25 mJ/m² and has at least one of a fluorine atom or a silicon atom and a polarity conversion group.

The resin C is a resin that has a surface energy of more than 25 mJ/m².

The surface energy of the resin C is more than 25 mJ/m², and from the viewpoint of controlling uneven distribution of the resin C in the resist film, the surface energy is preferably 28 mJ/m² or more, and more preferably 32 mJ/m² or more. The upper limit is not particularly limited, but is 40 mJ/m² or less in many cases.

A method for measuring the surface energy of the resin C will be described in detail in Examples which will be described later, but a single film of the resin C is prepared, and static contact angles (°) of pure water and diiodomethane are measured using a contact angle meter (manufactured by Kyowa Interface Science Co., Ltd.). The surface energy of the single film is calculated by an Owens-Wendt method using the static contact angle of water and the static contact angle of diiodomethane thus obtained, and is taken as a surface energy of the resin C.

In addition, the surface energy of the resin D which will be described later is also calculated by the same method.

The polarity conversion group is preferably a group whose solubility increases in an alkali developer through decomposition by the action of the alkali developer. Examples of the polarity conversion group include a lactone group, a carboxylic acid ester group (—COO—), an acid anhydride group (—C(O)OC(O)—), an acid imido group (—NHCONH—), a carboxylic acid thioester group (—COS—), a carbonic acid ester group (—OC(O)O—), a sulfuric acid ester group (—OSO₂O—), and a sulfonic acid ester group (—SO₂O—).

With such groups, in a case where the resist film and the alkali developer are in contact with each other, a group whose solubility is increased in an alkali developer is generated on the surface of the resist film, and thus, the hydrophilicity is improved on the surface of the resist film and the wetting properties of the alkali developer are improved.

In addition, since an ester group directly linked to the main chain of a repeating unit in the acrylate group is deteriorated in “a function of causing the solubility in an alkali developer to increase through decomposition by the action of the alkali developer”, the ester group is not included in the polarity conversion group in the present invention.

(Repeating Unit Having Polarity Conversion Group)

The resin C preferably includes a repeating unit (c) having a polarity conversion group.

Examples of the repeating unit (c) include a repeating unit represented by General Formula (K0).

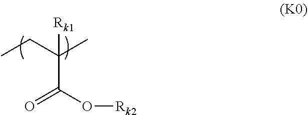

In the formula, Rₖ₁ represents a group including a polarity conversion group, a hydrogen atom, a halogen atom, a hydroxyl group, an alkyl group, a cycloalkyl group, or an aryl group.

Rₖ₂ represents a group including a polarity conversion group, an alkyl group, a cycloalkyl group, or an aryl group.

Here, at least one of Rₖ₁ or Rₖ₂ represents a group including a polarity conversion group.

In addition, the ester group directly linked to the main chain of the repeating unit represented by General Formula (K0) is not included in the polarity conversion group in the present invention as described above.

As the polarity conversion group, a group represented by X in a partial structure represented by General Formula (KA-1) or General Formula (KB-1) is preferable.

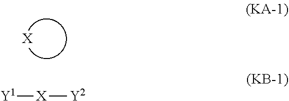

X in General Formula (KA-1) or General Formula (KB-1) represents a carboxylic acid ester group (—COO—), an acid anhydride group (—C(O)OC(O)—), an acid imido group (—NHCONH—), a carboxylic acid thioester group (—COS—), a carbonic acid ester group (—OC(O)O—), a sulfuric acid ester group (—OSO₂O—), or a sulfonic acid ester group (—SO₂O—).

Y¹ and Y² may be the same as or different from each other, and each represent an electron-withdrawing group.

Furthermore, the repeating unit (c) preferably has a group having a partial structure represented by General Formula (KA-1) or General Formula (KB-1). Incidentally, as in a case where the partial structure has no bonding arm as in a case of the partial structure represented by General Formula (KA-1) and the partial structure represented by General Formula (KB-1) in which Y¹ and Y² are monovalent, the group having the partial structure represented by General Formula (KA-1) or General Formula (KB-1) is a group having a monovalent or higher group formed by removing at least one of any hydrogen atoms in the partial structure represented by General Formula (KA-1) or General Formula (KB-1).

The partial structure represented by General Formula (KA-1) or General Formula (KB-1) may be linked to the main chain of the resin C via a substituent at any of positions. The partial structure represented by General Formula (KA-1) is a structure that forms a ring structure together with a group as X.

As X, a carboxylic acid ester group (that is, a case of forming a lactone ring structure as General Formula (KA-1)), an acid anhydride group, or a carbonic acid ester group is preferable, and the carboxylic acid ester group is more preferable.

The ring structure represented by General Formula (KA-1) may have a substituent, and may have, for example, nka substituents Zₖₐ₁'s.

In a case where a plurality of Zₖₐ₁'s are present, they each independently represent an alkyl group, a cycloalkyl group, an ether group, a hydroxyl group, an amido group, an aryl group, a lactone ring group, or an electron-withdrawing group.

Zₖₐ₁'s may be linked to each other to form a ring. Examples of the ring formed by the linking of Zₖₐ₁'s include a cycloalkyl ring and a hetero ring (a cyclic ether ring, a lactone ring, and the like).

nka represents an integer of 0 to 10, and is preferably an integer of 8 or less, more preferably an integer of 5 or less, still more preferably an integer of 4 or less, and particularly preferably an integer of 3 or less. The lower limit may be 1 or more.

The electron-withdrawing group represented by Zₖₐ₁ is the same as the electron-withdrawing group represented by each of Y¹ and Y² which will be described later.

In addition, the electron-withdrawing group may be substituted with another electron-withdrawing group.

In General Formula (KA-1), it is preferable that X is a carboxylic acid ester group and the partial structure represented by General Formula (KA-1) is a lactone ring, and it is more preferable that the partial structure is a 5- to 7-membered ring lactone ring. Another ring structure may be fused to the 5- to 7-membered ring lactone structure in a configuration to form a bicyclo structure or a spiro structure.

As a structure including the lactone ring structure represented by General Formula (KA-1), a structure represented by any one of General Formula (KA-1-1), . . . , or General Formula (KA-1-17) is preferable. Incidentally, the lactone ring structure may be directly bonded to the main chain. A structure represented by General Formula (KA-1-1), General Formula (KA-1-4), General Formula (KA-1-5), General Formula (KA-1-6), General Formula (KA-1-13), General Formula (KA-1-14), or General Formula (KA-1-17) is a preferred structure.

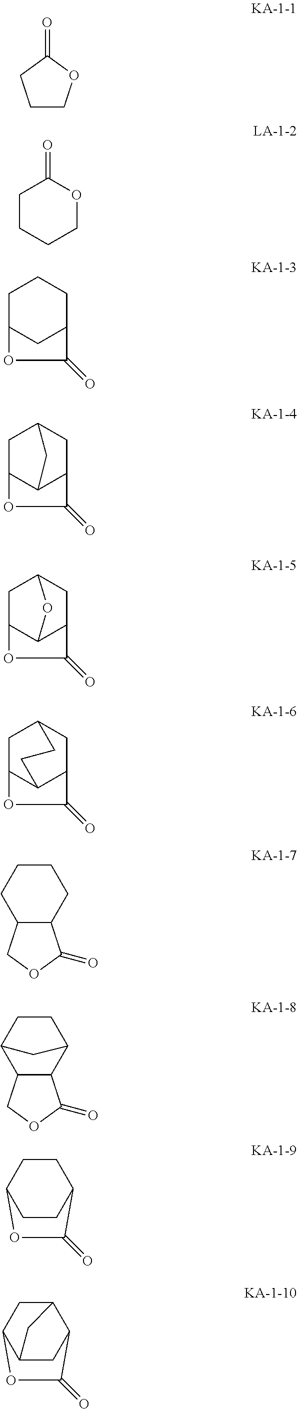

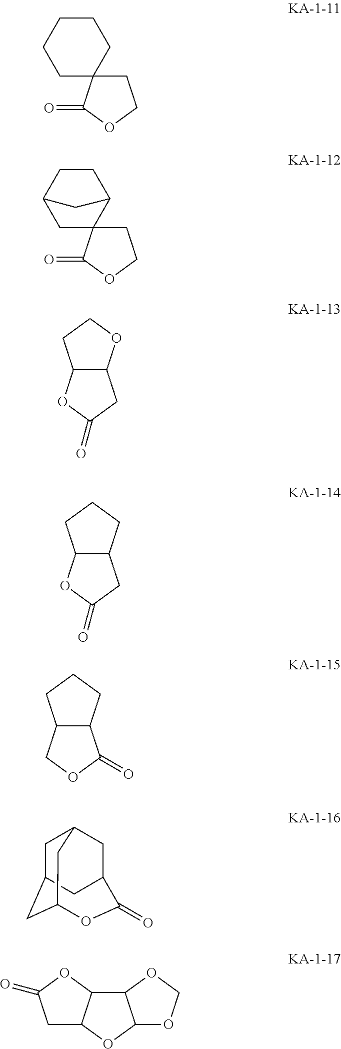

The structure including the lactone ring structure may have a substituent.

As X of General Formula (KB-1), a carboxylic acid ester group (—COO—) is preferable.

Y¹ and Y² in General Formula (KB-1) each independently represent an electron-withdrawing group.

Examples of the electron-withdrawing group include a group represented by General Formula (EW). * in General Formula (EW) represents a bonding arm directly linked to General Formula (KA-1) or a bonding arm directly linked to X in General Formula (KB-1).

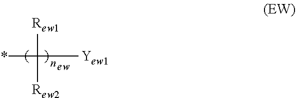

In General Formula (EW),

n_{ew} is a repetition number of linking groups represented by —C(R_{ew1})(R_{ew2})— and represents an integer of 0 or 1. In a case where n_{ew} is 0, it represents a single bond, indicating that Y_{ew1} is directly bonded.

Examples of Y_{ew1} include a halogen atom, a cyano group, a nitrile group, a nitro group, a halo(cyclo)alkyl group represented by —C(R_{f1})(R_{f2})—R_{f3}, a haloaryl group, an oxy group, a carbonyl group, a sulfonyl group, a sulfinyl group, and a combination thereof. Furthermore, the “halo(cyclo)alkyl group” represents an alkyl group and a cycloalkyl group, each of which is at least partly halogenated.

The electron-withdrawing group may be, for example, a group exemplified below.

R_{ew3} and R_{ew4} each independently represent any group. Even in a case where R_{ew3} and R_{ew4} are each of any groups, the group represented by General Formula (EW) has electron withdrawing properties. Among those, R_{ew3} and R_{ew4} are each preferably an alkyl group, a cycloalkyl group, or a fluorinated alkyl group.

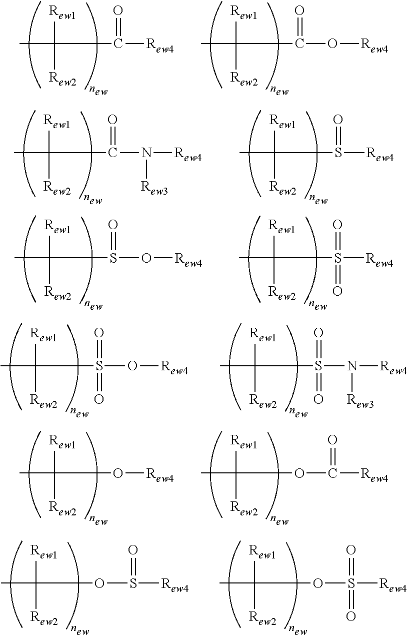

In a case where Y_{ew1} is a divalent or higher group, the remaining bonding arms form a bond with any atoms or substituents. At least any one group of Y_{ew1}, R_{ew1}, or R_{ew2} may be linked to the main chain of the resin C via an additional substituent.

As Y_{ew1}, a halogen atom, or a halo(cyclo)alkyl group or haloaryl group represented by —C(R_{f1})(R_{f2})—R_{f3} is preferable.

R_{ew1} and R_{ew2} each independently represent any substituent such as, for example, a hydrogen atom, an alkyl group, a cycloalkyl group, or an aryl group.

At least two of R_{ew1}, R_{ew2}, or Y_{ew1} may be linked to each other to form a ring.

R_{f1} represents a halogen atom, a perhaloalkyl group, a perhalocycloalkyl group, or a perhaloaryl group, and is preferably a fluorine atom, a perfluoroalkyl group, or a perfluorocycloalkyl group, and more preferably a fluorine atom or a trifluoromethyl group.

R_{f2} and R_{f3} each independently represent a hydrogen atom, a halogen atom or an organic group, and R_{f2} and R_{f3} may be linked to each other to form a ring. The organic group represents, for example, an alkyl group, a cycloalkyl group, an alkoxy group, a perhaloalkyl group, a perhalocycloalkyl group, or a perhaloaryl group. Among those, the alkyl group, the cycloalkyl group, the alkoxy group, the perfluoroalkyl group, or the perfluorocycloalkyl group is preferable as the organic group.

It is more preferable that R_{f2} represents the same group as R_{f1} or is linked to R_{f3} to form a ring.

R_{f1} to R_{f3} may be linked to each other to form a ring, and examples of the ring thus formed include a (halo)cycloalkyl ring and a (halo)aryl ring.

As a ring that may be formed by the mutual linking of at least two of R_{ew1}, R_{ew2}, or Y_{ew1}, a cycloalkyl group or a hetero ring group is preferable, and as the hetero ring group, a lactone ring group is preferable. Examples of the lactone ring include the structures represented by General Formula (KA-1-1) to General Formula (KA-1-17).

Moreover, the repeating unit (c) may have a plurality of partial structures represented by General Formula (KA-1) or a plurality of partial structures represented by General Formula (KB-1).

Furthermore, the repeating unit (c) may have both the partial structures of General Formula (KA-1) and General Formula (KB-1).

The repeating unit (c) may be any one of a repeating unit (c′) having at least one of a fluorine atom or a silicon atom and having a polarity conversion group on one side chain, a repeating unit (c*) having a polarity conversion group and not having a fluorine atom and a silicon atom, or a repeating unit (c″) having a polarity conversion group on one side chain and having a repeating unit (c″) having at least one of a fluorine atom or a silicon atom on a side chain different from the side chain in the same repeating unit.

Among those, the resin C more preferably has a repeating unit (c′) as the repeating unit (c).

In a case where the resin C has the repeating unit (c*), it is preferable that the resin C is a copolymer of the repeating unit (c*) and “a repeating unit having at least one of a fluorine atom or a silicon atom” which will be described later.

It is preferable that “the side chain having a polarity conversion group” and “the side chain having at least one of a fluorine atom or a silicon atom” in the repeating unit (c″) are bonded to the same carbon atom in the main chain, that is, that the side chains are in the positional relationship as shown in General Formula (4). In the formula, B1 represents a group having a polarity conversion group and B2 represents a group having at least one of a fluorine atom or a silicon atom.

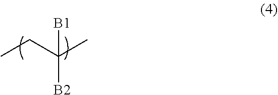

Moreover, in the repeating unit (c*) and the repeating unit (c″), the polarity conversion group is more preferably a partial structure in which X in the structure represented by General Formula (KA-1) is represented by —COO—.

As the partial structure represented by General Formula (KA-1), a partial structure represented by General Formula (KY-2) is preferable.

That is, the resin C preferably has a monovalent or higher group formed by removing at least one of any hydrogen atoms in the partial structure represented by General Formula (KY-2).

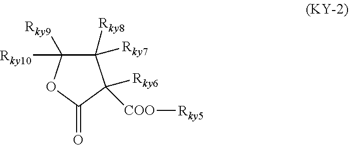

In General Formula (KY-2), R_{ky6} to R_{ky10} each independently represent a hydrogen atom, a halogen atom, an alkyl group, a cycloalkyl group, a carbonyl group, a carbonyloxy group, an oxycarbonyl group, an ether group, a hydroxyl group, a cyano group, an amido group, or an aryl group.

Two or more of R_{ky6} to R_{ky10} may be linked to each other to form a monocyclic or polycyclic structure.

R_{ky5} represents an electron-withdrawing group. Examples of the electron-withdrawing group include the same ones as the electron-withdrawing groups represented by Y₁ and Y₂ in General Formula (KB-1), and the electron-withdrawing group is preferably a halogen atom, or a halo(cyclo)alkyl group or haloaryl group represented by —C(R_{f1})(R_{f2})—R_{f3}.

The partial structure represented by General Formula (KY-2) is preferably a group represented by General Formula (KY-3). * represents a bonding position.

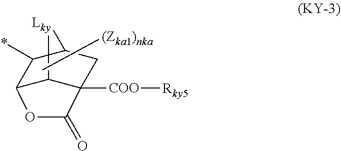

In General Formula (KY-3),

Zₖₐ₁ and nka each have the same definitions as Zₖₐ₁ and nka in General Formula (KA-1), respectively. R_{ky5} has the same definition as R_{ky5} in General Formula (KY-2).

L_{ky} represents an alkylene group, an oxygen atom, or a sulfur atom. Examples of the alkylene group of L_{ky} include a methylene group and an ethylene group. L_{ky} is preferably an oxygen atom or a methylene group, and more preferably the methylene group.

The repeating unit (c) is preferably a repeating unit obtained by polymerization such as addition polymerization, condensation polymerization, and addition condensation, and more preferably a repeating unit obtained by addition polymerization of a carbon-carbon double bond. Examples thereof include repeating units such as a (meth)acrylate-based repeating unit (including the system having a substituent at the α- or β-position), a styrene-based repeating unit (including the system having a substituent at the α- or β-position), a vinyl ether-based repeating unit, a norbornene-based repeating unit, and a maleic acid derivative (maleic anhydride or a derivative thereof, maleimide, and the like) repeating unit. The (meth)acrylate-based repeating unit, the styrene-based repeating unit, the vinyl ether-based repeating unit, or the norbornene-based repeating unit is preferable, the (meth)acrylate-based repeating unit, the vinyl ether-based repeating unit, or the norbornene-based repeating unit is more preferable, and the (meth)acrylate-based repeating unit is still more preferable.

The resin C preferably includes a repeating unit having a group represented by General Formula (2).

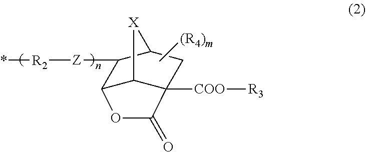

In General Formula (2),
R₂ represents a chained or cyclic alkylene group, and in a case where a plurality of R₂'s are present, they may be the same as or different from each other.
R₃ represents a linear, branched, or cyclic hydrocarbon group in which the hydrogen atoms are partly or fully substituted with fluorine atoms.
R₄ represents a halogen atom, a cyano group, a hydroxyl group, an amido group, an alkyl group, a cycloalkyl group, an alkoxy group, a phenyl group, an acyl group, an alkoxycarbonyl group, R—C(═O)—, or a group represented by R—C(═O)O— (R represents an alkyl group or a cycloalkyl group). In a case where a plurality of R₄'s are present, they may be the same as or different from each other, and two or more of R₄'s may be bonded to each other to form a ring.

X represents an alkylene group, an oxygen atom, or a sulfur atom.
Z represents a single bond, an ether bond, an ester bond, an amide bond, a urethane bond, or a urea bond, and in a case where a plurality of Z's are present, they may be the same as or different from each other.
* represents a bonding position.
n represents a repetition number and represents an integer of 0 to 5.
m is the number of substituents and represents an integer of 0 to 7.

As the structure of —R₂—Z—, a structure represented by —(CH₂)ₗ—COO— is preferable (l represents an integer of 1 to 5).

Specific examples of the repeating unit (c) having a polarity conversion group include the repeating units described in paragraphs 0315 to 0316 of JP2015-143881A, the contents of which are herein incorporated by reference.

The content of the repeating unit (c) is preferably 10% to 100% by mole, more preferably 209% to 100% by mole, still more preferably 30% to 100% by mole, and particularly preferably 40% to 100% by mole, with respect to all the repeating units in the resin C.

The content of the repeating unit (c′) is preferably 10% to 100% by mole, more preferably 20% to 100% by mole, still more preferably 30% to 100%/o by mole, and particularly preferably 40% to 100% by mole, with respect to all the repeating units in the resin C.

The content of the repeating unit (c*) is preferably 10% to 90% by mole, more preferably 15% to 85% by mole, still more preferably 20%0 to 80% by mole, and particularly preferably 25% to 75% by mole, with respect to all the repeating units in the resin C.

The content of “the repeating unit having at least one of a fluorine atom or a silicon atom”, which will be described later, used in combination with the repeating unit (c*) is preferably 10% to 90% by mole, more preferably 15% to 85% by mole, still more preferably 20 to 80% by mole, and particularly preferably 25% to 75% by mole, with respect to all the repeating units in the resin C.

The content of the repeating unit (c″) is preferably 10% to 100% by mole, more preferably 20% to 100% by mole, still more preferably 30% to 100% by mole, and particularly preferably 40% to 100% by mole, with respect to all the repeating units in the resin C.

(Repeating Unit Having at Least One of Fluorine Atom or Silicon Atom)

The resin C may include a repeating unit having at least one of a fluorine atom or a silicon atom. Incidentally, a polarity conversion group is not included in the repeating unit.

Examples of the repeating unit having at least one of a fluorine atom or a silicon atom include a repeating unit having a fluorine atom, a repeating unit having a silicon atom, and a repeating unit having both a fluorine atom and a silicon atom, and the repeating unit having a fluorine atom is preferable.

The repeating unit having a fluorine atom preferably has an alkyl group having a fluorine atom, a cycloalkyl group having a fluorine atom, or an aryl group having a fluorine atom.

The alkyl group having a fluorine atom (preferably having 1 to 10 carbon atoms, and more preferably having 1 to 4 carbon atoms) is a linear or branched alkyl group in which at least one hydrogen atom is substituted with a fluorine atom, and may further have another substituent.

The cycloalkyl group having a fluorine atom is a monocyclic or polycyclic cycloalkyl group in which at least one hydrogen atom is substituted with a fluorine atom, and may further have another substituent.

Examples of the aryl group having a fluorine atom include an aryl group such as a phenyl group and a naphthyl group, in which at least one hydrogen atom is substituted with a fluorine atom, and the aryl group may further have another substituent.

As the alkyl group having a fluorine atom, the cycloalkyl group having a fluorine atom, or the aryl group having a fluorine atom, a group represented by any one of General Formula (F2), . . . , or (F4) is preferable.

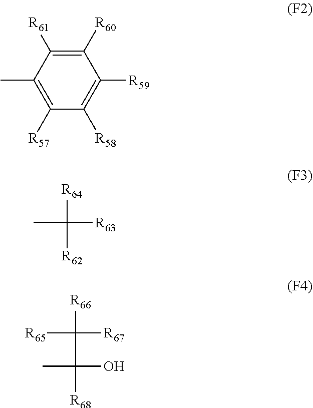

In General Formulae (F2) to (F4),

R₅₇ to R₆₈ each independently represent a hydrogen atom, a fluorine atom, or an (linear or branched) alkyl group, provided that at least one of R₅₇, . . . , or R₆₁, at least one of R₆₂, . . . or R₆₄, and at least one of R₆₅, . . . , or R₆₈ each independently represent a fluorine atom or an alkyl group (preferably having 1 to 4 carbon atoms) in which at least one hydrogen atom is substituted with a fluorine atom.

It is preferable that all of R₅₇ to R₆₁, and R₆₅ to R₆₇ are fluorine atoms. R₆₂, R₆₃, and R₆₈ are each preferably a fluoroalkyl group (preferably having 1 to 4 carbon atoms), and more preferably a perfluoroalkyl group having 1 to 4 carbon atoms. R₆₂ and R₆₃ may be linked to each other to form a ring.

Specific examples of the group represented by General Formula (F2) include a p-fluorophenyl group, a pentafluorophenyl group, and a 3,5-di(trifluoromethyl)phenyl group.

Specific examples of the group represented by General Formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, and a perfluorocyclohexyl group.

Specific examples of the group represented by General Formula (F4) include —C(CF₃)₂OH, —C(C₂F₅)₂OH, —C(CF₃)(CH₃)OH, and —CH(CF₃)OH.

The alkyl group having a fluorine atom, the cycloalkyl group having a fluorine atom, or the aryl group having a fluorine atom may be directly bonded to the main chain of the resin C.

In addition, the alkyl group having a fluorine atom, the cycloalkyl group having a fluorine atom, or the aryl group having a fluorine atom may also be bonded via one group or a combination of two or more groups, selected from the group consisting of an alkylene group, a phenylene group, an ether group, a thioether group, a carbonyl group, an ester group, an amido group, a urethane group, and a ureylene group.

Suitable examples of the repeating unit having a fluorine atom include the following ones shown below.

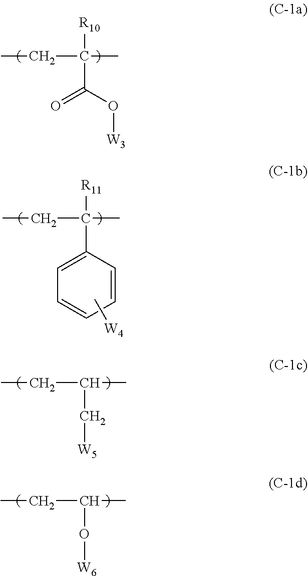

In the formulae, R₁₀ and R₁₁ each independently represent a hydrogen atom, a fluorine atom, or an alkyl group (preferably a linear or branched alkyl group having 1 to 4 carbon atoms; examples of the alkyl group having a substituent include a fluorinated alkyl group).

W₃ to W₆ each independently represent an organic group including at least one or more fluorine atoms. Specific examples thereof include the group represented by any one of General Formula (F2), . . . , or (F4).

The repeating unit having a silicon atom preferably has an alkylsilyl structure (preferably a trialkylsilyl group) or a group having a cyclic siloxane structure.

Specific examples of the alkylsilyl structure or the cyclic siloxane structure include groups represented by General Formulae (CS-1) to (CS-3).

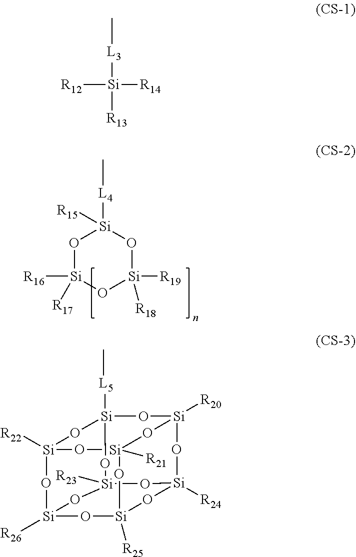

In General Formulae (CS-1) to (CS-3),

R₁₂ to R₂₆ each independently represent a linear or branched alkyl group (preferably having 1 to 20 carbon atoms) or a cycloalkyl group (preferably having 3 to 20 carbon atoms).

L³ to L⁵ each independently represent a single bond or a divalent linking group. Examples of the divalent linking group include one group or a combination of two or more groups selected from the group consisting of an alkylene group, a phenylene group, an ether group, a thioether group, a carbonyl group, an ester group, an amido group, a urethane group, and a ureylene group.

n represents an integer of 1 to 5.

Furthermore, examples of the repeating unit having both a fluorine atom and a silicon atom include a repeating unit having the group represented by any one of General Formula (F2) . . . . , or (F4) and the group represented by any one of General Formula (CS-1), . . . , or (CS-3).

(Styrene Derivative-Derived Repeating Unit)

The resin C may include a styrene derivative-derived repeating unit.

As the styrene derivative-derived repeating unit, a repeating unit represented by General Formula (ST) is preferable.

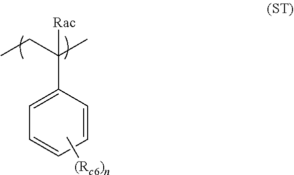

In General Formula (ST), R_{c6}, represents an alkyl group, a cycloalkyl group, an alkenyl group, a cycloalkenyl group, an alkoxycarbonyl group, or an alkylcarbonyloxy group. As R_{c6}, a t-butyl group is preferable.

The alkyl group is preferably a linear or branched alkyl group having 1 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The alkoxycarbonyl group is preferably an alkoxycarbonyl group having 2 to 20 carbon atoms.

The alkylcarbonyloxy group is preferably an alkylcarbonyloxy group having 2 to 20 carbon atoms.

Rac represents a hydrogen atom, an alkyl group which may be substituted with a fluorine atom, a cyano group, or a —CH₂—O-Rac₂ group. In the formula, Rac₂ represents a hydrogen atom, an alkyl group, or an acyl group. Rac is preferably a hydrogen atom, a methyl group, a hydroxymethyl group, or a trifluoromethyl group, and more preferably a hydrogen atom or a methyl group.

n represents an integer of 0 to 5. In a case where n is 2 or more, a plurality of R's may be the same as or different from each other.

As R_{c6}, an unsubstituted alkyl group or an alkyl group substituted with a fluorine atom is preferable, and a trifluoromethyl group or a t-butyl group is more preferable.

The content of the styrene derivative-derived repeating unit is preferably 0% to 30% by mole, more preferably 3% to 20% by mole, and still more preferably 5% to 15% by mole, with respect to all the repeating units of the resin C.

(Repeating Unit Having Alkali-Soluble Group)

The resin C may include a repeating unit having an alkali-soluble group.

Examples of the alkali-soluble group include a phenolic hydroxyl group, a carboxylic acid group, a fluorinated alcohol group, a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group.

Examples of the repeating unit having an alkali-soluble group include a repeating unit in which an alkali-soluble group is directly bonded to the main chain of a resin, such as an acrylic acid- or methacrylic acid-derived repeating unit, and a repeating unit in which an alkali-soluble group is bonded to the main chain of a resin via a linking group. In addition, an alkali-soluble group can also be introduced into a terminal of a polymer chain using a polymerization initiator or chain transfer agent having the alkali-soluble group during polymerization.

The content of the repeating unit having an alkali-soluble group is preferably 1% to 50% by mole, more preferably 3% to 35% by mole, and still more preferably 5% to 30% by mole, with respect to all the repeating units in the resin C.

(Other Repeating Units)

The resin C may include a repeating unit which has neither a fluorine atom nor a silicon atom, is stable against an acid, and is sparingly soluble or insoluble in an alkali developer (hereinafter also referred to as a “repeating unit X”).

As the repeating unit X, a repeating unit represented by General Formula (CIII) is preferable.

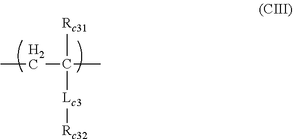

In General Formula (CIII),

R_{c31} represents a hydrogen atom, an alkyl group which may be substituted with a fluorine atom, a cyano group, or a —CH₂—O-Rac₂ group. In the formula, Rac₂ represents a hydrogen atom, an alkyl group, or an acyl group. R_{c31} is preferably a hydrogen atom, a methyl group, a hydroxymethyl group, or a trifluoromethyl group, and more preferably a hydrogen atom or a methyl group.

R_{c32} represents an alkyl group, a cycloalkyl group, an alkenyl group, or a cycloalkenyl group.

L₃ represents a single bond or divalent linking group.

The alkyl group represented by R_{c32} is preferably a linear or branched alkyl group having 3 to 20 carbon atoms.

The cycloalkyl group represented by R_{c32} is preferably a cycloalkyl group having 3 to 20 carbon atoms.

The alkenyl group represented by R_{c32} is preferably an alkenyl group having 3 to 20 carbon atoms.

The cycloalkenyl group represented by R_{c32} is preferably a cycloalkenyl group having 3 to 20 carbon atoms.

The divalent linking group represented by L_{c3} is preferably an ester group, an amido group, an alkylene group (preferably having 1 to 5 carbon atoms), or an oxy group.

The content of the repeating unit X is preferably 1% to 40% by mole, and more preferably 1% to 30% by mole, with respect to all the repeating units in the resin C.

The weight-average molecular weight of the resin C as a value in terms of polystyrene by a gel permeation chromatography (GPC) method is preferably 1,000 to 100,000, more preferably 1,000 to 50,000, and still more preferably 2,000 to 15,000.

The molecular weight distribution (weight-average molecular weight (Mw)/number-average molecular weight (Mn)) of the resin C is not particularly limited, but is preferably 1.0 to 2.5, and more preferably 1.0 to 2.0.

The content of the resin C in the composition of the embodiment of the present invention is not particularly limited, but is preferably 0.1% to 10% by mass, and more preferably 0.5% to 5% by mass, with respect to the total solid content of the composition, in view of a balance between the water repellency of a resist film and the hydrophilicity of the resist film after being in contact with the alkali developer.

Furthermore, the resin C may be used alone or in combination of a plurality thereof.

In addition, the total solid content is intended to mean a sum of components constituting the resist film, and the solvent is not included in the solid content.

<Resin D that has Surface Energy of 25 mJ/m² or Less>

The resin D is a resin having a surface energy of 25 mJ/m² or less.

The surface energy of the resin D is 25 mJ/m² or less, and from the viewpoint of controlling uneven distribution of the resin D in the resist film, the surface energy is preferably 23 mJ/m² or less, and more preferably 20 mJ/m² or less. The lower limit is not particularly limited, but is 15 mJ/m² or more in many cases.

Furthermore, in view of controlling uneven distribution of the resin C and the resin D in the resist film, a difference between the surface energy of the resin C and the surface energy of the resin D {(the surface energy of the resin C)−(the surface energy of the resin D)} is preferably 5 mJ/m² or more from the above viewpoint. The upper limit is not particularly limited, but is 20 mJ/m² or less in many cases.

A method for measuring the surface energy of the resin D is the same as the above-mentioned method for measuring the surface energy of the resin C.

A type of the repeating unit included in the resin D is not particularly limited, but the repeating unit having at least one of a fluorine atom or a silicon atom which may be included in the above-mentioned resin C is preferably included, and the repeating unit having a fluorine atom is more preferably included.

The content of the repeating unit having at least one of a fluorine atom or a silicon atom in the resin D is preferably 1% to 100% by mole, more preferably 1% to 99% by mole, and still more preferably 5% to 96% by mole, with respect to all the repeating units in the resin D, in view of more excellent water repellency of the resist film.

Only one kind or a plurality of kinds of the repeating units having at least one of a fluorine atom or a silicon atom may be included.

The repeating unit having a polarity conversion group included in the above-mentioned resin C may be included in the resin D.

In a case where the repeating unit having a polarity conversion group is included in the resin D, the content of the repeating unit having a polarity conversion group in the resin D is preferably 0.1% to 20% by mole, and more preferably 1% to 10% by mole, with respect to all the repeating units in the resin D, in view of more excellent water repellency of the resist film.

The repeating unit having an alkali-soluble group which may be included in the above-mentioned resin C may be included in the resin D.

In a case where the repeating unit having an alkali-soluble group is included in the resin D, the content of the repeating unit having an alkali-soluble group in the resin D is preferably 0.1% to 5% by mole, and more preferably 0.5% to 3% by mole, with respect to all the repeating units in the resin D, in view of more excellent water repellency of the resist film.

The above-mentioned styrene derivative-derived repeating unit which may be included in the resin C may be included in the resin D.

In a case where the styrene derivative-derived repeating unit is included in the resin D, the content of the styrene derivative-derived repeating unit in the resin D is preferably 0.1% to 40% by mole, and more preferably 0.5% to 20% by mole, with respect to all the repeating units in the resin D, in view of more excellent water repellency of the resist film.

The repeating unit X which may be included in the above-mentioned resin C may be included in the resin D.

In a case where the repeating unit X is included in the resin D, the content of the repeating unit in the resin D is preferably 0.1% to 20% by mole, and more preferably 1% to 10% by mole, with respect to all the repeating units in the resin D, in view of more excellent water repellency of the resist film.

The weight-average molecular weight of the resin D as a value in terms of polystyrene by a GPC method is preferably 1,000 to 100,000, and more preferably 1,000 to 50,000.

The molecular weight distribution (weight-average molecular weight (Mw)/number-average molecular weight (Mn)) of the resin D is not particularly limited, but is preferably 1.0 to 2.0, and more preferably 1.0 to 1.7.

The content of the resin D in the composition of the embodiment of the present invention is 1.1% by mass or more with respect to the total solid content of the composition, and in view of a more excellent balance between the water repellency of a resist film and the hydrophilicity of the resist film after being in contact with the alkali developer, the content is preferably 1.1% to 10% by mass, more preferably 1.1%6 to 5% by mass.

In addition, the resin D may be used alone or in combination of a plurality thereof.

Moreover, the mass ratio of the resin D to the resin C (the mass of the resin D/the mass of the resin C) is not particularly limited, but in view of a more excellent balance between the water repellency of a resist film and the hydrophilicity of the resist film after being in contact with the alkali developer, the mass ratio is preferably 0.1 or more, and more preferably 0.3 to 5.

<Resin A Whose Solubility in Alkali Developer Increases by Action of Acid>

The resin A is a resin whose solubility in an alkali developer increases by the action of an acid, which is a resin having a group that decomposes by the action of an acid in the main chain or a side chain, or both the main chain and the side chain of the resin to generate an alkali-soluble group (hereinafter also referred to as an “acid-decomposable group”). That is, as the acid-decomposable group, an alkali-soluble group whose hydrogen atom is substituted with a group that leaves by an acid is preferable.

Examples of the alkali-soluble group include the alkali-soluble groups described in the resin C.

Examples of the group that leaves by an acid include —C(R₃₆)(R₃₇)(R₃₈) and —C(R₀₁)(R₀₂)(OR₃₉).

In the formula. R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ and R₀₂ each independently represent a hydrogen atom, an alkyl group, a cycloalkyl group, an aryl group, an aralkyl group, or an alkenyl group.

As the acid-decomposable group, a cumyl ester group, an enol ester group, an acetal ester group, or a tertiary alkyl ester group is preferable.

The resin A preferably includes a repeating unit having an acid-decomposable group. As the repeating unit having an acid-decomposable group, a repeating unit represented by General Formula (AI) is preferable.

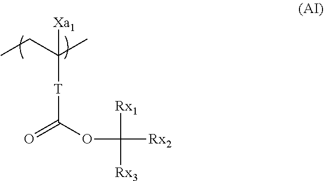

In General Formula (AI),

Xa₁ represents a hydrogen atom, a methyl group, a trifluoromethyl group, or a hydroxymethyl group. T represents a single bond or a divalent linking group.

Rx₁ to Rx₃ each independently represent an (linear or branched) alkyl group or a (monocyclic or polycyclic) cycloalkyl group.

At least two of Rx₁, . . . , or Rx₃ may be bonded to each other to form a (monocyclic or polycyclic) cycloalkyl group.

Examples of the divalent linking group of T include an alkylene group, a —COO-Rt-group, and an —O-Rt- group. In the formulae, Rt represents an alkylene group or a cycloalkylene group.

An aspect in which Rx₁ is a methyl group or an ethyl group, and Rx₂ and Rx₃ are bonded to each other to form the above-mentioned cycloalkyl group, and/or an aspect in which at least one of Rx₁ . . . , or Rx₃ is the above-mentioned cycloalkyl group is preferable.

The —C(Rx)(Rx₂)(Rx₃) group which is an acid-decomposable group in General Formula (AI) may have a group represented by at least one -(L)ₙ₁-P as a substituent. Here, L represents a divalent linking group, n₁ represents 0 or 1, and P represents a polar group.

Examples of the divalent linking group of L include a linear or branched alkylene group and a cycloalkylene group. The number of atoms of the divalent linking group is preferably 20 or less, and more preferably 15 or less. The linear or branched alkylene group and the cycloalkylene group preferably have 8 or less carbon atoms. The linear or branched alkylene group and the cycloalkylene group may have a substituent, and examples of the substituent include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms).

Examples of the polar group of P include heteroatom-including groups such as a hydroxyl group, a ketone group, a cyano group, an amido group, an alkylamido group, a sulfonamido group, a lower ester group, and a lower sulfonate group. Here, the lower group is preferably the group having 2 or 3 carbon atoms. As the polar group, a hydroxyl group, a cyano group, or an amido group is preferable, and the hydroxyl group is more preferable.

Examples of the group represented by -(L)ₙ₁-P include, in a case of n1=1, a linear or branched alkyl group (preferably having 1 to 10 carbon atoms) or a cycloalkyl group (preferably having 3 to 15 carbon atoms), which has a hydroxyl group, a cyano group, an amino group, an alkylamido group, an acid amido group, or a sulfonamido group, and preferably include an alkyl group (preferably having 1 to 5 carbon atoms, and more preferably having 1 to 3 carbon atoms) having a hydroxyl group.

Among those, the group in which P is a hydroxyl group, n1 is 0 or 1, an L is a linear or branched alkylene group (preferably having 1 to 5 carbon atoms) is preferable.

The group represented by —C(Rx₁)(Rx₂)(Rx₃) in General Formula (AI) preferably has one to three groups represented by -(L)ₙ₁-P, more preferably one or two groups represented by -(L)ₙ₁-P, and still more preferably one group represented by -(L)ₙ₁-P, more preferably.

As the repeating unit represented by General Formula (AI), a repeating unit represented by General Formula (1-1) is preferable.

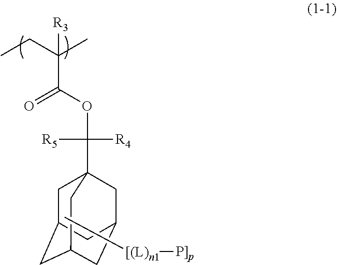

In General Formula (1-1),

R₃ is the same as Xₐ₁ in General Formula (AI).

R₄ and R₅ are the same as Rx₁ and Rx₂ in General Formula (AI).

The group represented by -(L)ₙ₁-P is the same as the group represented by -(L)ₙ₁-P for General Formula (AI).

p represents an integer of 1 to 3, and is preferably 1 or 2, and more preferably 1.

A monomer corresponding to the repeating unit represented by General Formula (AI) can be synthesized, for example, by the method described in JP2006-016379A.

Suitable aspects of the acid-decomposable group include the repeating units described in paragraphs 0049 to 0054 of JP2010-044358A (hereinafter referred to “Document A”), the contents of which are herein incorporated by reference.

The content of the repeating unit having an acid-decomposable group is preferably 20% to 50% by mole, and more preferably 25% to 45% by mole, with respect to all the repeating units in the resin A.

The resin A preferably further includes a repeating unit having at least one group selected from the group consisting of a lactone group, a hydroxyl group, a cyano group, and an alkali-soluble group, and more preferably includes a repeating unit having a lactone group (lactone structure).

The repeating unit having a lactone structure, which can be included in the resin A, will be described.

As the lactone structure, any one can be used, but 5- to 7-membered ring lactone structures are preferable. Furthermore, it is also preferable that another ring structure is fused to the 5- to 7-membered ring lactone structures in the form of forming a bicyclo structure or a spiro structure.

The resin A more preferably includes a repeating unit having a lactone structure represented by any one of General Formula (LC1-1), . . . , or (LC1-17). Furthermore, the lactone structure may be directly bonded to the main chain. Preferred examples of the lactone structure include a lactone structure represented by General Formula (LC1-1). General Formula (LC1-4), General Formula (LC1-5), General Formula (LC1-6), General Formula (LC1-13), General Formula (LC1-14), or General Formula (LC1-17).

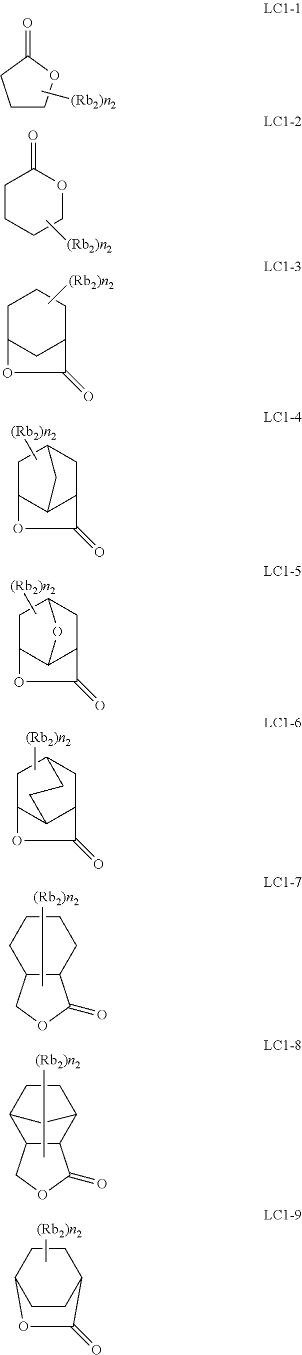

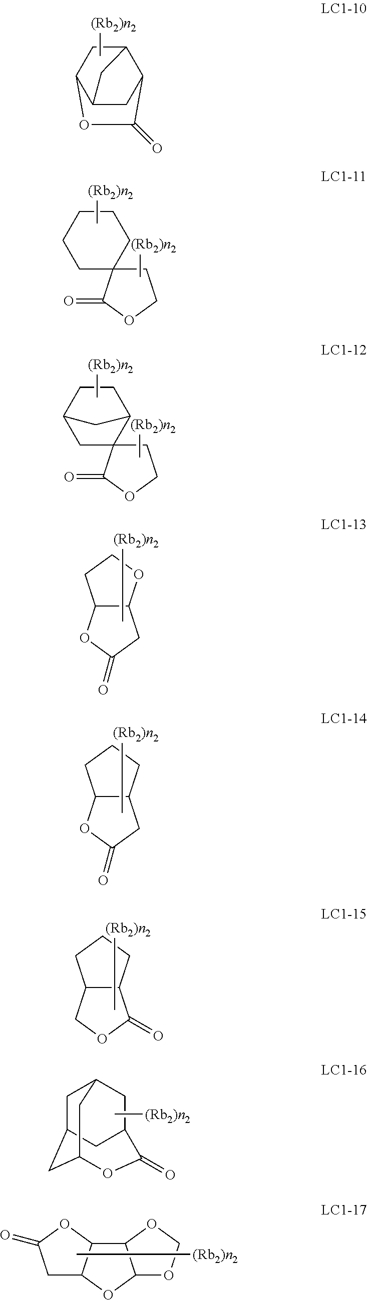

The lactone structure moiety may have a substituent (Rb₂). As the substituent (Rb₂), an alkyl group having 1 to 8 carbon atoms (a hydrogen atom in the alkyl group may be substituted with a fluorine atom), a cycloalkyl group having 4 to 7 carbon atoms, an alkoxy group having 1 to 8 carbon atoms, an alkoxycarbonyl group having 1 to 8 carbon atoms, a carboxyl group, a halogen atom, a hydroxyl group, a cyano group, or an acid-decomposable group is preferable, and an alkyl group having 1 to 4 carbon atoms, a cyano group, or an acid-decomposable group is more preferable, n₂ represents an integer of 0 to 4. In a case where n₂ is 2 or more, the substituents (Rb₂) which are present in plural number may be the same as or different from each other and the substituents (Rb₂) which are present in plural number may be bonded to each other to form a ring.

Specific examples of the repeating unit having a lactone structure represented by any one of General Formula (LC1-1) . . . . , or General Formula (LC1-17) include a repeating unit represented by General Formula (AII).

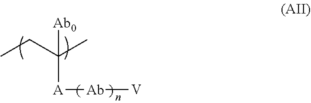

In General Formula (AII),

Ab₀ represents a hydrogen atom, a halogen atom, or an alkyl group having 1 to 4 carbon atoms, may have a substituent. Ab₀ may have an alkyl group. Preferred examples of the substituent include a hydroxyl group and a halogen atom. Examples of the halogen atom of Ab₀ include a fluorine atom, a chlorine atom, a bromine atom, and an iodine atom. As Ab₀, a hydrogen atom a methyl group, a hydroxymethyl group, or a trifluoromethyl group is preferable, and a hydrogen atom or a methyl group is more preferable.

A represents a —COO— group or a —CONH— group.

Ab represents a single bond, an alkylene group, a divalent linking group having a monocyclic or polycyclic alicyclic hydrocarbon structure, an ether bond, ester bond, carbonyl group, an amide bond, urethane bond, urea bond, or a divalent linking group formed by combination thereof. Among those, a single bond or a divalent linking group represented by -Ab₁-CO₂— is preferable.

Ab₁ represents a linear or branched alkylene group, or a monocyclic or polycyclic cycloalkylene group, and is preferably a methylene group, an ethylene group, a cyclohexylene group, an adamantylene group, or a norbornylene group.

n represents an integer of 1 to 5. n is preferably 1 or 2, and more preferably 1.

V represents a group having a structure represented by any one of General Formula (LC1-1), . . . . or General Formula (LC1-17).

Specific examples of the repeating unit including a lactone structure include the repeating units described in paragraphs 0064 to 0067 of Document A, the contents of which are herein incorporated by reference.

The resin A preferably includes a repeating unit including a lactone structure represented by General Formula (3).

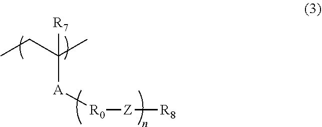

In General Formula (3),

A represents an ester bond (—COO—) or an amide bond (—CONH—).

In a case where a plurality of R₀'s are present, they each independently represent an alkylene group, a cycloalkylene group, or a combination thereof.

In a case where a plurality of Z's are present, they each independently represent an ether bond, an ester bond, a carbonyl group, an amide bond, a urethane bond, or a urea bond.

R₈ represents a monovalent organic group having a lactone structure.

n represents an integer of 1 to 5. n is preferably 1 or 2, and more preferably 1.

R₇ represents a hydrogen atom, a halogen atom, or an alkyl group which may have a substituent.

The alkylene group or cyclic alkylene group represented by R₀ may have a substituent.

Z is preferably an ether bond or an ester bond, and more preferably an ester bond.

Examples of the repeating unit including a lactone structure represented by General Formula (3) include the repeating units described in paragraph 0079 of Document A, the contents of which are herein incorporated by reference.

As the repeating unit having a lactone structure, a repeating unit represented by General Formula (3-1) is more preferable.

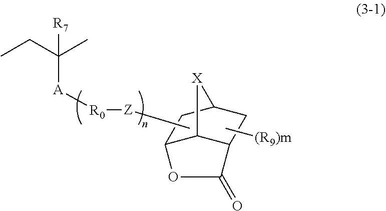

In General Formula (3-1),

R₇, A, R₀, Z, and n have the same definitions as in General Formula (3).

In a case where a plurality of R₉'s are present, they each independently represent an alkyl group, a cycloalkyl group, an alkoxycarbonyl group, a cyano group, a hydroxyl group, or an alkoxy group, and in a case where a plurality of R₉'s are present, two of R₉'s may be bonded to each other to form a ring.

X represents an alkylene group, an oxygen atom, or a sulfur atom.

m represents an integer of 0 to 5. m is preferably 0 or 1. In a case of m=1, it is preferable that R₉ is substituted at the α- or β-position of the carbonyl group of the lactone, and it is more preferable that R₉ is substituted at the α-position.

As the alkyl group of R₉, an alkyl group having 1 to 4 carbon atoms is preferable, and a methyl group or an ethyl group is more preferable. Examples of the cycloalkyl group include a cyclopropyl group, a cyclobutyl group, a cyclopentyl group, and a cyclohexyl group. Examples of the alkoxycarbonyl group include a methoxycarbonyl group, an ethoxycarbonyl group, an n-butoxycarbonyl group, and a t-butoxycarbonyl group. As R₉, a methyl group, a cyano group, or an alkoxycarbonyl group is preferable, and a cyano group is more preferable.

Examples of the alkylene group of X include a methylene group and an ethylene group. As X, an oxygen atom or a methylene group is preferable, and the methylene group is more preferable.

Specific examples of the repeating unit including a lactone structure represented by General Formula (3-1) include the repeating units described in paragraphs 0083 to 0084 of Document A, the contents of which are herein incorporated by reference.

The content of the repeating unit having a lactone group is preferably 15% to 60% by mole, more preferably 20% to 50% by mole, and still more preferably 30% to 50% by mole, with respect to all the repeating units in the resin A.

The resin A may include a repeating unit having a hydroxyl group or a cyano group, which is not included in General Formula (AT) and General Formula (All).

As the repeating unit having a hydroxyl group or a cyano group, a repeating unit having an alicyclic hydrocarbon structure substituted with a hydroxyl group or a cyano group is preferable. As the alicyclic hydrocarbon structure substituted with a hydroxyl group or a cyano group, an adamantyl group, a diadamantyl group, or a norbomane group is preferable. As the alicyclic hydrocarbon structure substituted with a hydroxyl group or a cyano group, partial structures represented by General Formulae (VIIa) to (VIId) are preferable.

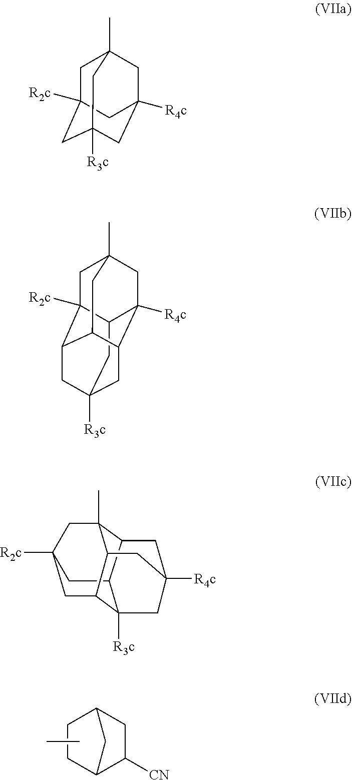

In General Formulae (VIIa) to (VIIc),

R₂c to R₄c each independently represent a hydrogen atom, a hydroxyl group, or a cyano group, provided that at least one of R₂c, . . . , or R₄c represents a hydroxyl group or a cyano group. It is preferable that one or two of R₂c, . . . , or R₄c are each a hydroxyl group while the remainder is a hydrogen atom. It is more preferable that two of R₂c, . . . , or R₄c are a hydroxyl group and the remainder is a hydrogen atom in General Formula (VIIa).

In Examples of the repeating unit having a partial structure represented by each of General Formulae (VIIa) to (VIId) include the repeating units described in paragraphs 0090 and 0091 of Document A, the contents of which are herein incorporated by reference.

The content of the repeating unit having a hydroxyl group or a cyano group is preferably 5% to 40% by mole, more preferably 5% to 30% by mole, and still more preferably 10% to 25% by mole, with respect to all the repeating units in the resin A.

The resin A may include a repeating unit having an alkali-soluble group. Examples of the repeating unit having an alkali-soluble group include the repeating units having an alkali-soluble group which may be included in the resin C.

The resin A may further include a repeating unit represented by General Formula (I), which has neither a hydroxyl group nor a cyano group.

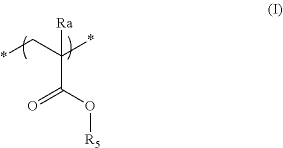

In General Formula (I), R₅ represents a hydrocarbon group which has at least one cyclic structure, and has neither a hydroxyl group nor a cyano group.

Ra represents a hydrogen atom, an alkyl group, or a —CH₂—O—Ra₂ group. Ra₂ represents a hydrogen atom, an alkyl group, or an acyl group. Examples of Ra include a hydrogen atom, a methyl group, a trifluoromethyl group, and a hydroxymethyl group.

Furthermore, it is preferable that the resin A includes neither a fluorine atom nor a silicon atom.

The resin A can be synthesized in accordance with an ordinary method (for example, radical polymerization). Examples of the general synthesis method include a bulk polymerization method in which polymerization is carried out by dissolving monomer species and an initiator in a solvent and heating the solution, a dropwise addition polymerization method in which a solution of monomer species and an initiator is added dropwise to a heating solvent for 1 to 10 hours, and the dropwise addition polymerization method is preferable.

The weight-average molecular weight of the resin A as a value in terms of polystyrene by a GPC method is preferably 1,000 to 200,000, more preferably 2,000 to 20,000, still more preferably 3,000 to 15,000, and particularly preferably 5,000 to 13,000.

The molecular weight distribution (weight-average molecular weight (Mw)/number-average molecular weight (Mn)) of the resin A is not particularly limited, but is preferably 1.0 to 2.0, and more preferably 1.0 to 1.7.

The content of the resin A in the composition of the embodiment of the present invention is not particularly limited, but is preferably 50% to 99%6 by mass, and more preferably 70% to 98% by mass, with respect to the total solid content of the composition.

Furthermore, the resins A may be used alone or in combination of a plurality of kinds thereof.

<Compound B that Generates Acid Upon Irradiation with Actinic Rays or Radiation>

The composition of the embodiment of the present invention includes a compound that generates an acid upon irradiation with actinic rays or radiation (hereinafter also referred to as an “acid generator”).

As the acid generator, a photoinitiator for cationic photopolymerization, a photoinitiator for radical photopolymerization, a photodecoloring agent for coloring agents, a photodiscoloring agent, a known compound that generates an acid upon irradiation with actinic rays or radiation, for use in a microresist or the like, and a mixture thereof may be mentioned.

Examples of the acid generator include a diazonium salt, a phosphonium salt, a sulfonium salt, an iodonium salt, imidosulfonate, oxime sulfonate, diazodisulfone, disulfone, and o-nitrobenzyl sulfonate.

Moreover, a compound that generates an acid with the light described in U.S. Pat. No. 3,779,778A, EP126712A, or the like can also be used.

As the acid generator, a compound represented by General Formula (ZI), (ZII), or (ZIII) is preferable.

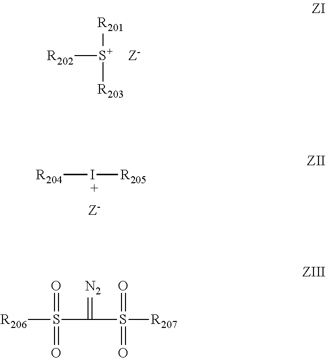

In General Formula (ZI),

R₂₀₁, R₂₀₂, and R₂₀₃ each independently represent an organic group.

The number of carbon atoms of the organic group as each of R₂₀₁, R₂₀₂, and R₂₀₃ is generally 1 to 30, and preferably 1 to 20.

Furthermore, two of R₂₀₁ to R₂₀₃ may be bonded to each other to form a ring structure, and the ring may include an oxygen atom, a sulfur atom, an ester bond, an amide bond, or a carbonyl group, and examples of the group formed by the bonding of two of R₂₀₁ to R₂₀₃ include an alkylene group (for example, a butylene group and a pentylene group).

Z⁻ represents a non-nucleophilic anion.

Examples of the non-nucleophilic anion as Z⁻ include a sulfonate anion, a carboxylate anion, a sulfonylimide anion, a bis(alkylsulfonyl)imide anion, and a tris(alkylsulfonyl)methyl anion.

The non-nucleophilic anion is an anion having a noticeably low ability for causing a nucleophilic reaction, and is also an anion that can suppress temporal decomposition caused by an intra-molecular nucleophilic reaction.

As the compound represented by General Formula (ZI), a compound (ZI-1), a compound (ZI-2), or a compound (ZI-3) shown below is preferable.

The compound (ZI-1) is a compound having an arylsulfonium compound, that is, arylsulfonium as a cation, in which at least one of R₂₀₁, . . . , or R₂₀₃ in General Formula (ZI) is an aryl group.

Next, the compound (ZI-2) will be described.

The compound (ZI-2) is a compound in which R₂₀₁ to R₂₀₃ in General Formula (ZI) each independently represent an organic group not having an aromatic ring. Here, the aromatic ring also encompasses an aromatic ring including a heteroatom.

The compound (ZI-3) is a compound represented by General Formula (ZI-3), which includes a phenacylsulfonium salt structure.

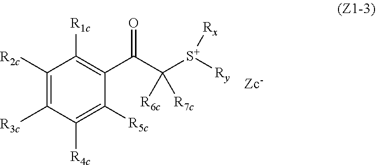

In General Formula (ZI-3),

R_{1c} to R_{5c} each independently represent a hydrogen atom, an alkyl group, a cycloalkyl group, an alkoxy group, or a halogen atom.

R_{6c} and R_{7c} each independently represent a hydrogen atom, an alkyl group, or a cycloalkyl group.

Rₓ and R_{y} each independently represent an alkyl group, a cycloalkyl group, an allyl group, or a vinyl group.

Any two or more of R_{1c}, . . . , or R_{5c}, R_{6c} and R_{7c}, and Rₓ and R_{y} may be bonded to each other to form a ring structure, and the ring structure may include an oxygen atom, a sulfur atom, an ester bond, or an amide bond. Examples of the group formed by the bonding of any two or more of R_{1c}, . . . , or R_{5c}, R_{6c} and R_{7c}, and Rₓ and R_{y} include a butylene group and a pentylene group.

Z_{c}⁻ represents a non-nucleophilic anion, and examples thereof include the same non-nucleophilic anions as Z⁻ in General Formula (ZI).

In General Formulae (ZII) an (ZIII).

R₂₀₄ to R₂₀₇ each independently represent an aryl group, an alkyl group, or a cycloalkyl group.

The aryl group of each of R₂₀₄ to R₂₀₇ is preferably a phenyl group or a naphthyl group, and more preferably a phenyl group. The aryl group of each of R₂₀₄ to R₂₀₇ may be an aryl group having a heterocyclic structure including an oxygen atom, a nitrogen atom, a sulfur atom, or the like. Examples of the aryl group including a heterocyclic structure include a pyrrole residue (a group formed by loss of one hydrogen atom from pyrrole), a furan residue (a group formed by loss of one hydrogen atom from furan), a thiophene residue (a group formed by loss of one hydrogen atom from thiophene), an indole residue (a group formed by loss of one hydrogen atom from indole), a benzofuran residue (a group formed by loss of one hydrogen atom from benzofuran), and a benzothiophene residue (a group formed by loss of one hydrogen atom from benzothiophene).

Z_{c}⁻ represents a non-nucleophilic anion, and examples thereof include the same ones as the non-nucleophilic anion of Z⁻ in General Formula (ZI).

Examples of the acid generator include a compound represented by General Formula (ZIV), General Formula (ZV), or General Formula (ZVI).

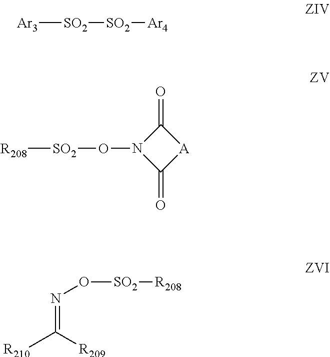

In General Formula (ZIV) to (ZVI),

Ar₃ and Ar₄ each independently represent an aryl group.

R₂₀₈, R₂₀₉, and R₂₁₀ each independently represent an alkyl group, a cycloalkyl group, or an aryl group.

A represents an alkylene group, an alkenylene group, or an arylene group.

As the acid generator, the compounds represented by General Formulae (ZI) to (ZIII) are preferable.

Furthermore, as the acid generator, a compound that generates an acid including one sulfonic acid group or imido group is preferable, and a compound that generates a monovalent perfluoroalkanesulfonic acid, a compound that generates an aromatic sulfonic acid substituted with a monovalent fluorine atom or a group including a fluorine atom, or a compound that generates an imide acid substituted with a monovalent fluorine atom or a group including a fluorine atom is more preferable.

Among the acid generators, preferred examples thereof are shown below.

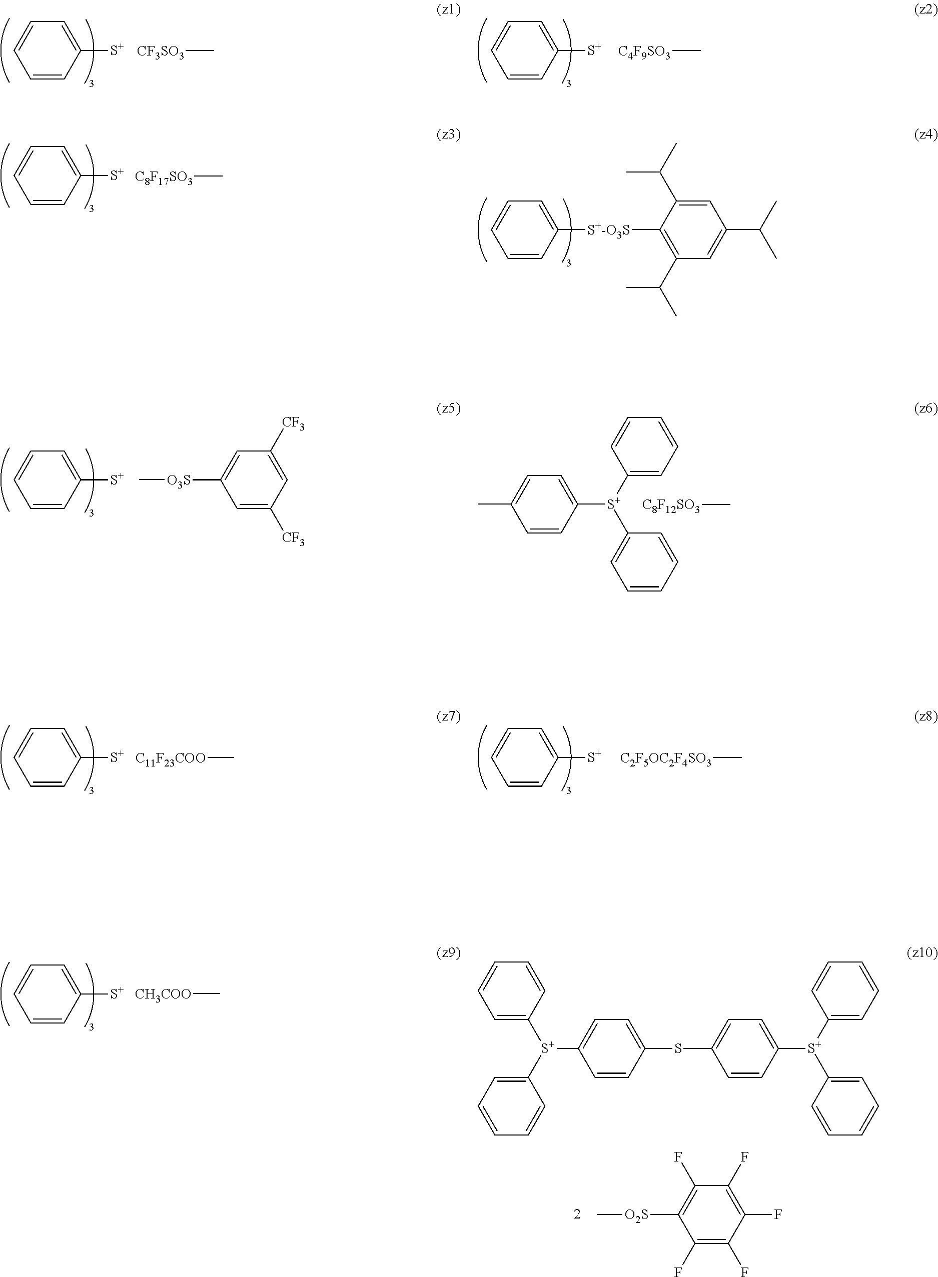

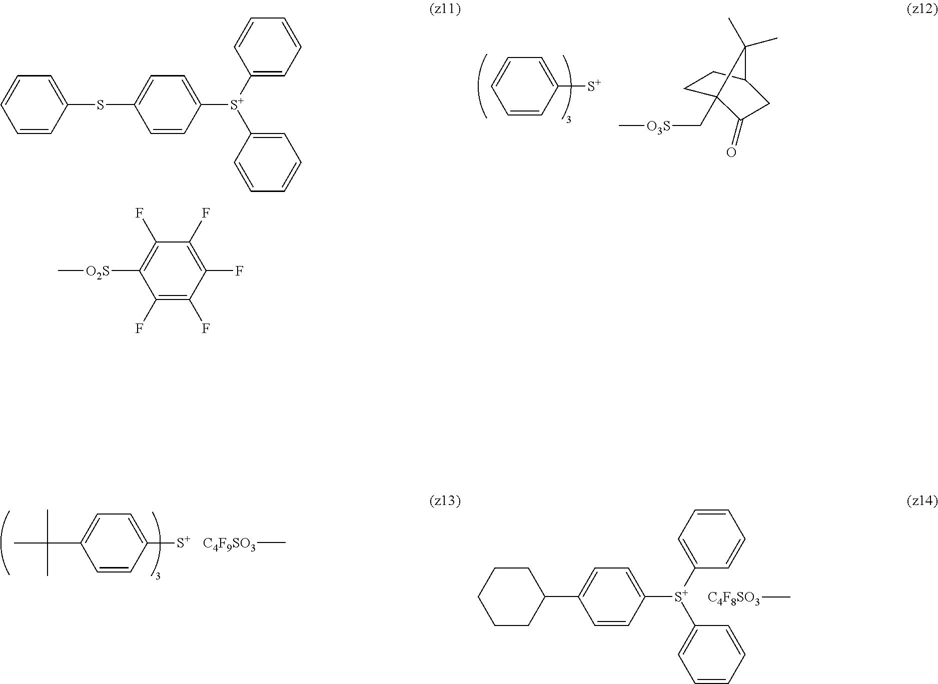

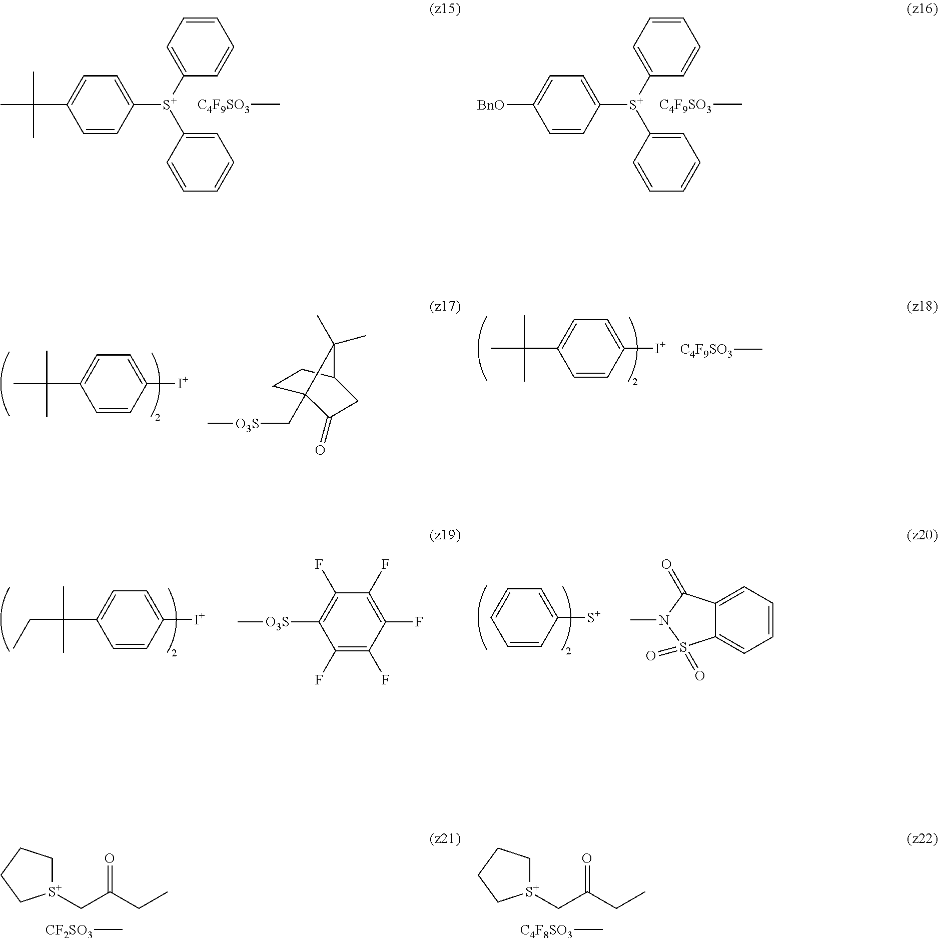

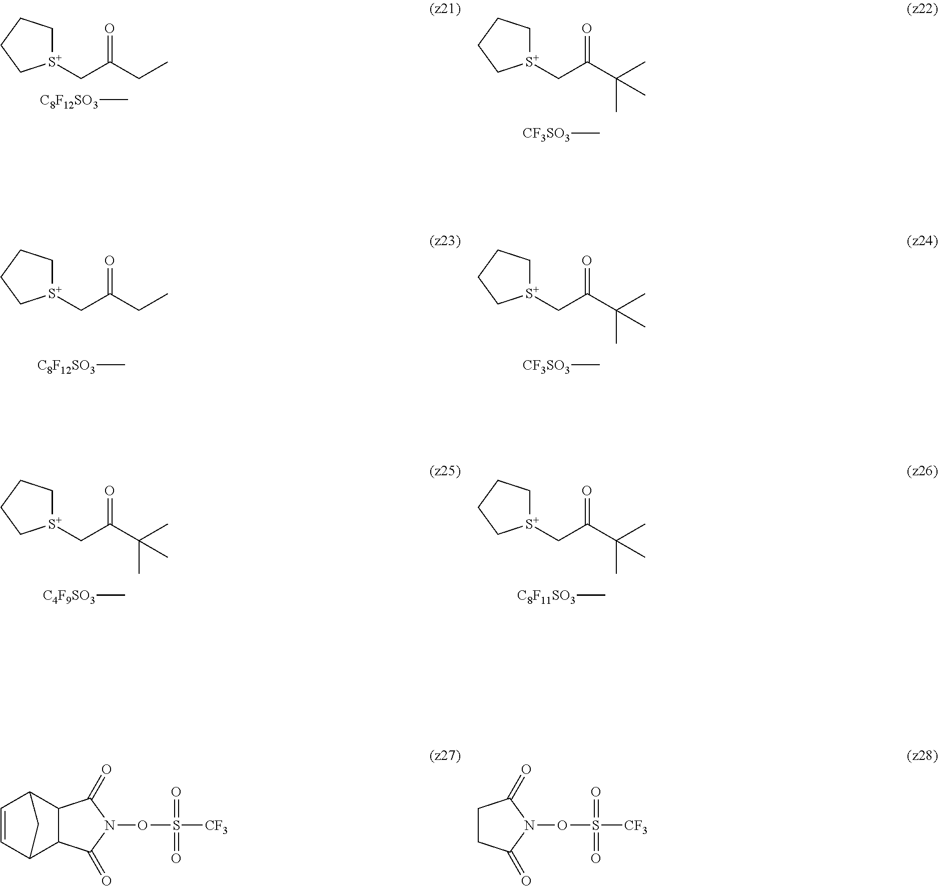

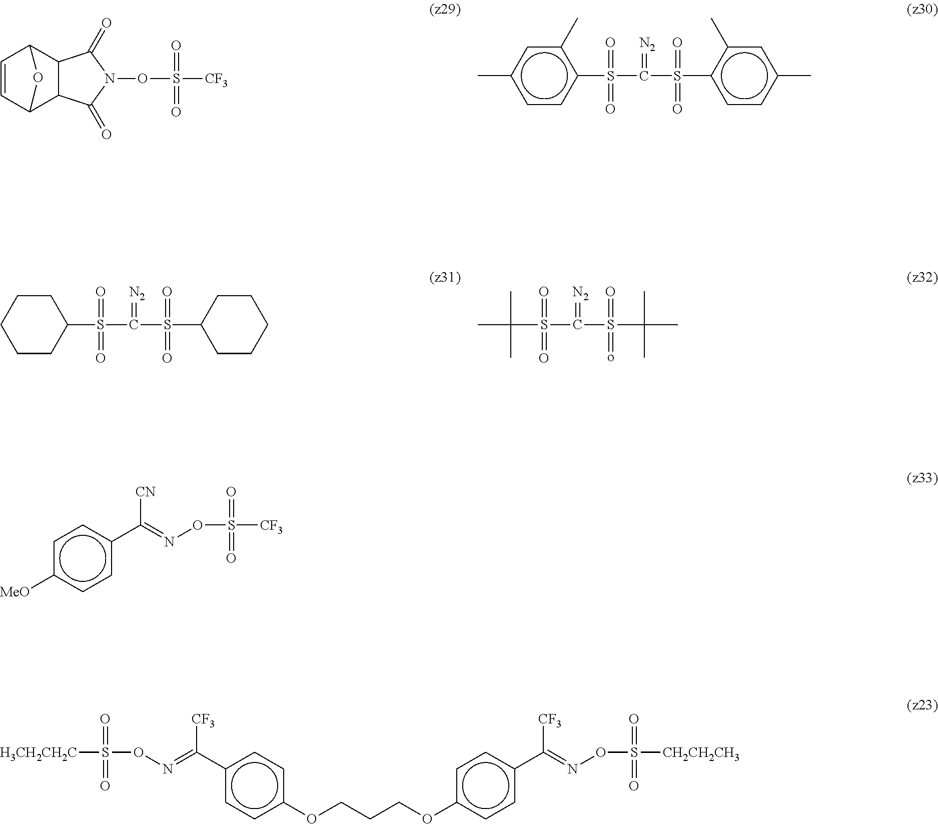

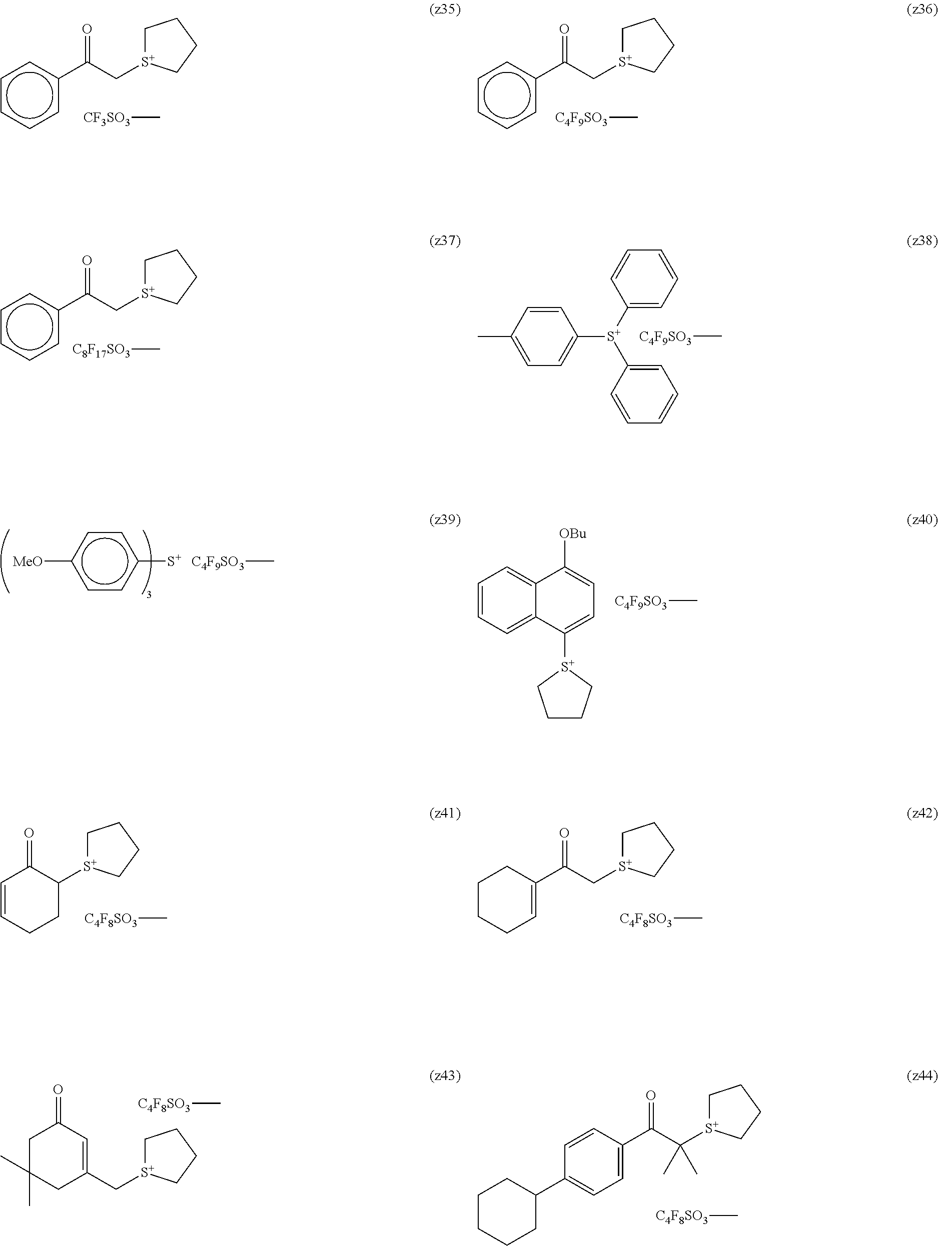

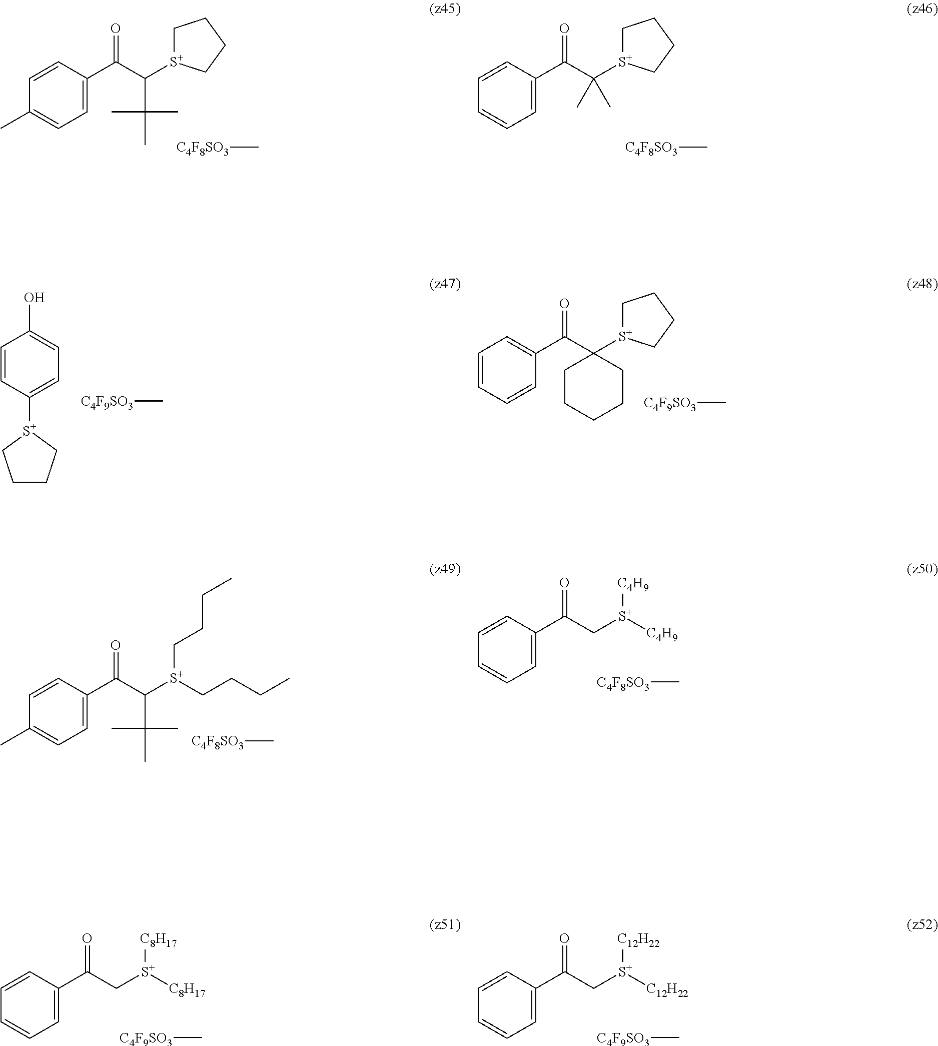

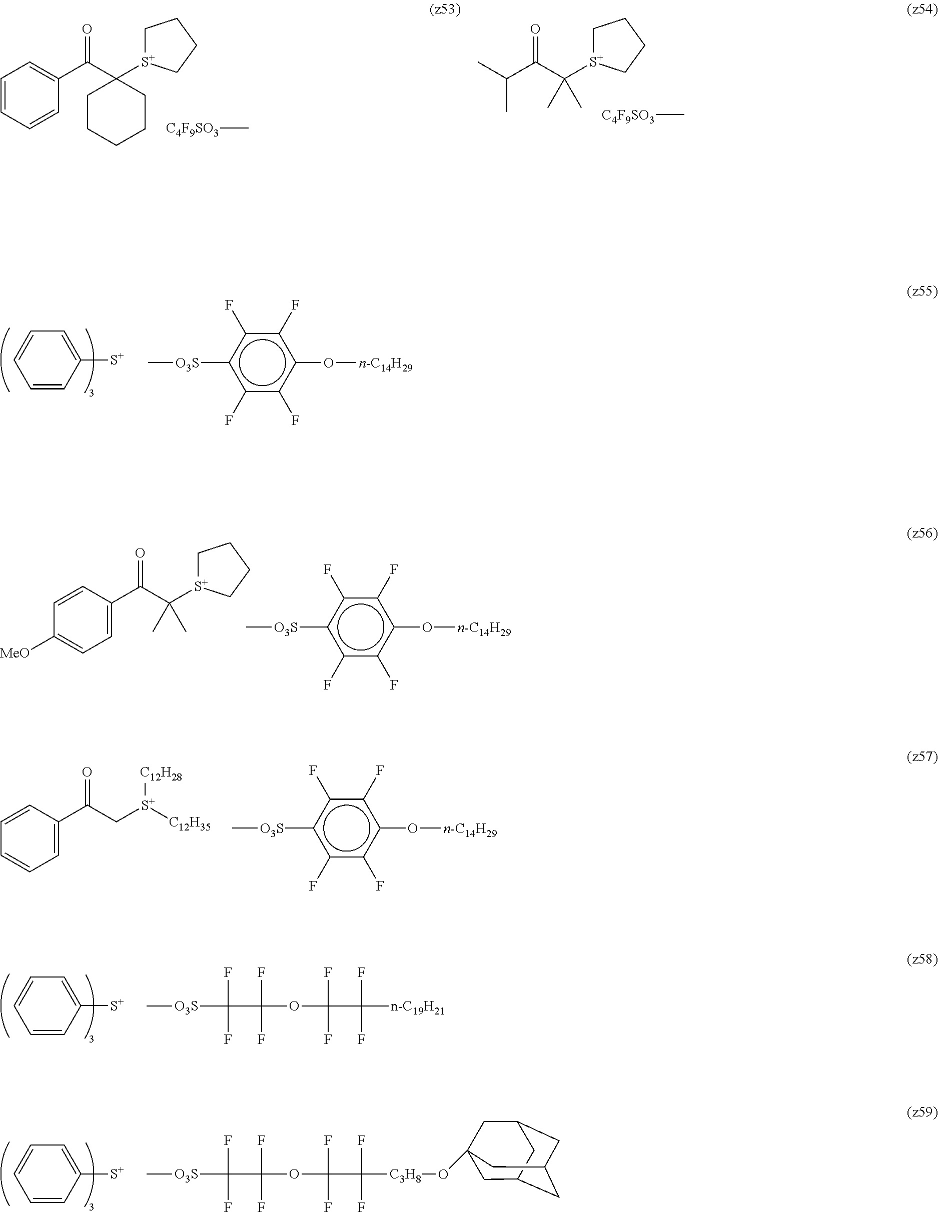

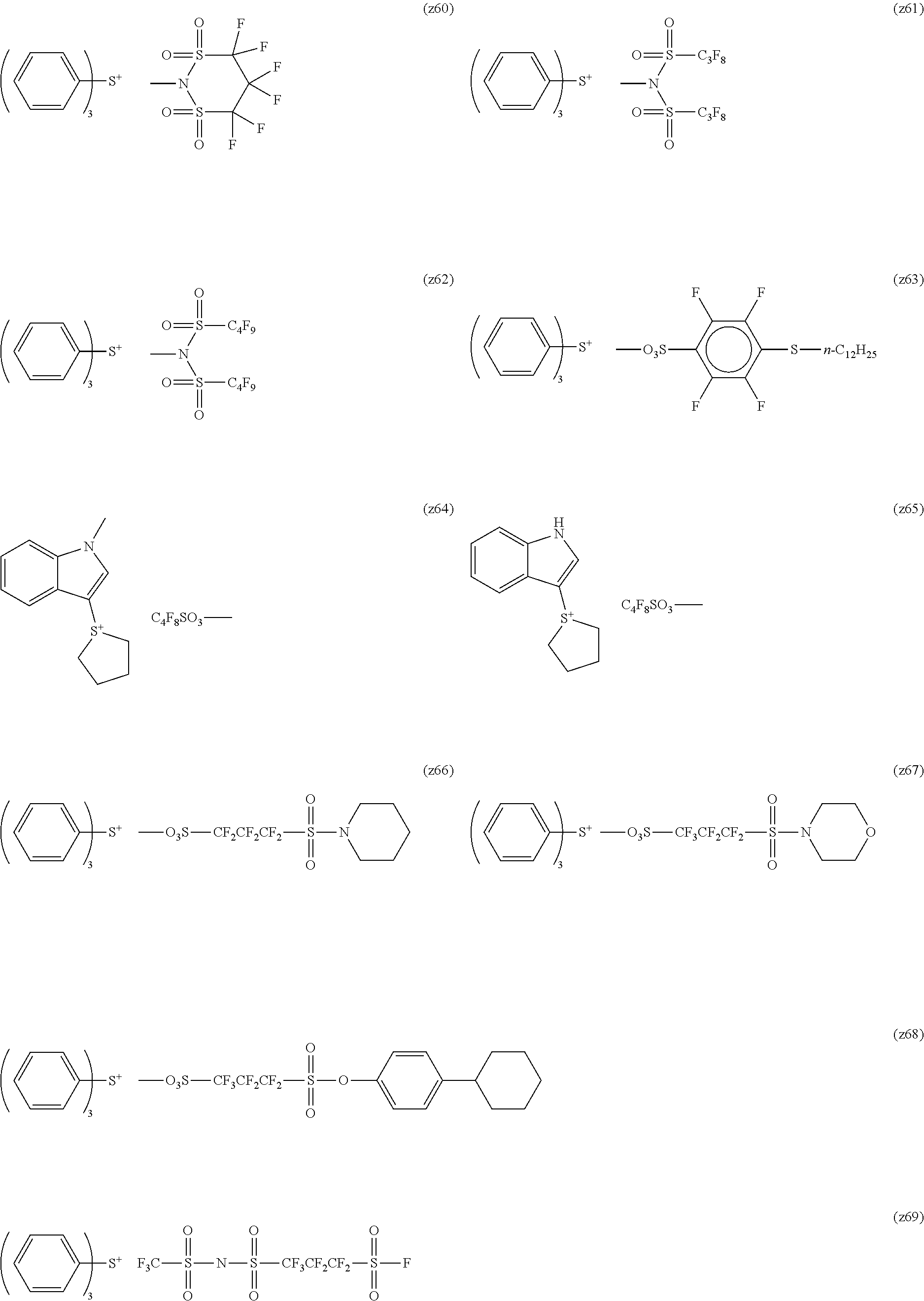

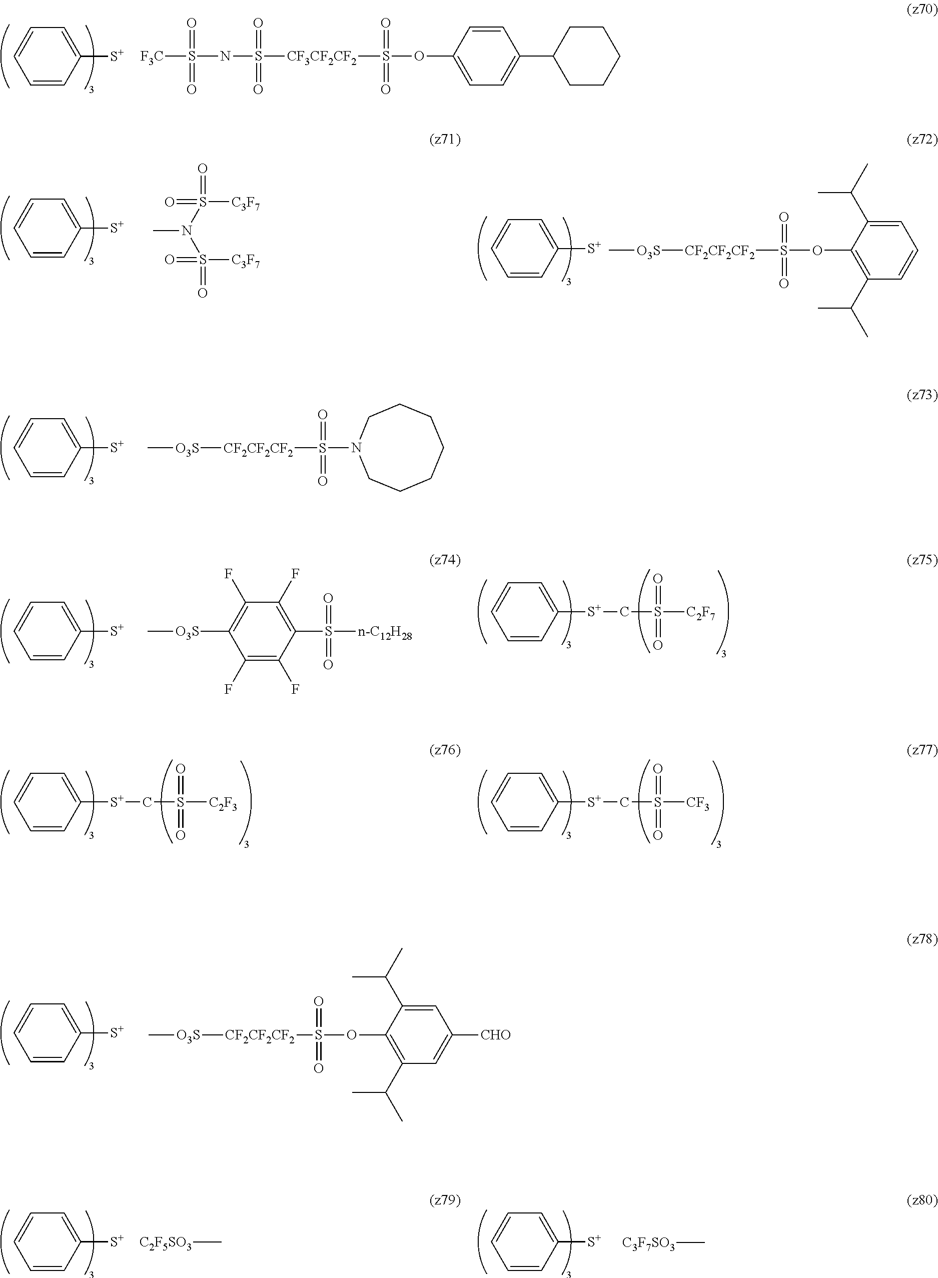

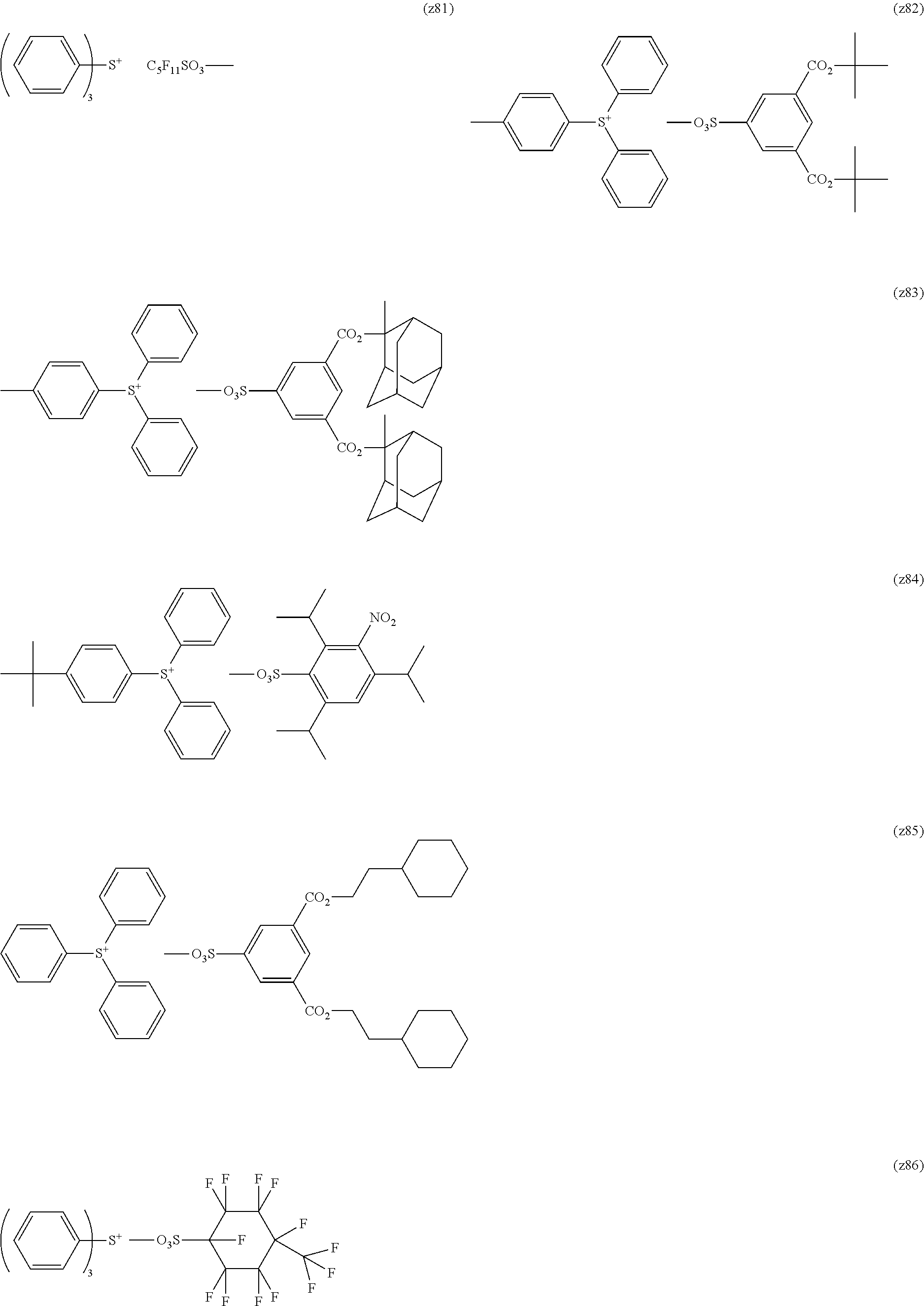

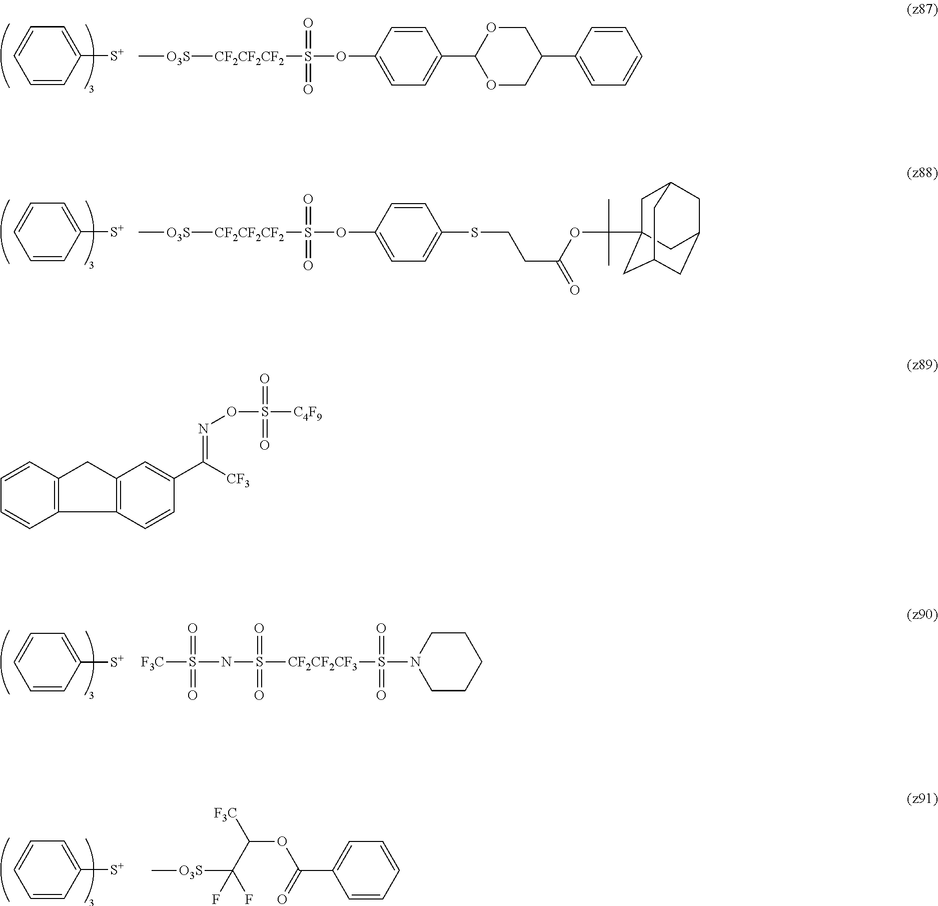

The content of the acid generator in the composition of the embodiment of the present invention is not particularly limited, but is preferably 0.1% to 20% by mass, and more preferably 0.5 to 10% by mass, with respect to the total solid content of the composition.

Furthermore, the acid generators may be used alone or in combination of a plurality thereof.

<Optional Components>

The actinic ray-sensitive or radiation-sensitive resin composition may include components other than the above components. Examples of the components other than the above components include a solvent and a basic compound.

(Solvent)

The composition of the embodiment of the present invention may include a solvent.

Examples of the solvent which can be used in the preparation of an actinic ray-sensitive or radiation-sensitive resin composition by dissolving the respective components include organic solvents such as alkylene glycol monoalkyl ether carboxylate, alkylene glycol monoalkyl ether, alkyl lactate ester, alkyl alkoxypropionate, a cyclic lactone (preferably having 4 to 10 carbon atoms), a monoketone compound (preferably having 4 to 10 carbon atoms), alkylene carbonate, alkyl alkoxyacetate, and alkyl pyruvate.

Specific examples of the alkylene glycol monoalkyl ether carboxylate, the alkylene glycol monoalkyl ether, the alkyl lactate ester, the cyclic lactone, monoketone compound, the alkylene carbonate, the alkyl alkoxyacetate, and the alkyl pyruvate each are each described in paragraph 0227, paragraph 0228, paragraph 0229, paragraph 0230, paragraph 0231, paragraph 0232, and paragraph 0233 of Document A, the contents of which are herein incorporated by reference. Furthermore, preferred examples of the solvent include the solvents described in paragraph 0234 of Document A, the contents of which are herein incorporated by reference.

The solvents may be used alone or in combination of two or more kinds thereof.

Among those, an aspect in which the composition includes two or more solvents, and the boiling point of at least one solvent of the two or more solvents is 140° C. or higher is preferable in view of more excellent water repellency of the resist film. Furthermore, a composition including a first solvent having a boiling point of 140° C. or higher and a second solvent having a higher boiling point than the first solvent is more preferable.

Incidentally, the boiling point of the first solvent is 140° C. or higher, and preferably 145° C. or higher. The upper limit of the boiling point of the first solvent is not particularly limited, but is 170° C. or lower in many cases.

The boiling point of the second solvent is not particularly limited as long as it is higher than the boiling point of the first solvent, but is preferably 5° C. or higher than the boiling point of the first solvent. The upper limit of the boiling point of the second solvent is not particularly limited, but is (the boiling point of the first solvent+100° C.) or less in many cases.

The mass ratio of the mass of the second solvent to the mass of the first solvent (the second solvent/the first solvent) is not particularly limited, but is preferably 0.01 to 1, and more preferably 0.02 to 0.5, in view of more excellent water repellency of the resist film.

Incidentally, the boiling point is intended to mean a boiling point at 1 atm.

The concentration of the total solid content of the composition of the embodiment of the present invention is preferably 1% to 10% by mass, more preferably 1% to 8% by mass, and still more preferably 1% to 6% by mass.

(Basic Compound)

The composition of the embodiment of the present invention may include a basic compound in order to reduce a change in performance over time from exposure to heating. Furthermore, aspects of the basic compound are described in paragraph 0238 to paragraph 0250 of Document A, the contents of which are herein incorporated by reference.

Preferred compounds as the basic compound are specifically shown below, but the basic compound is not limited thereto.

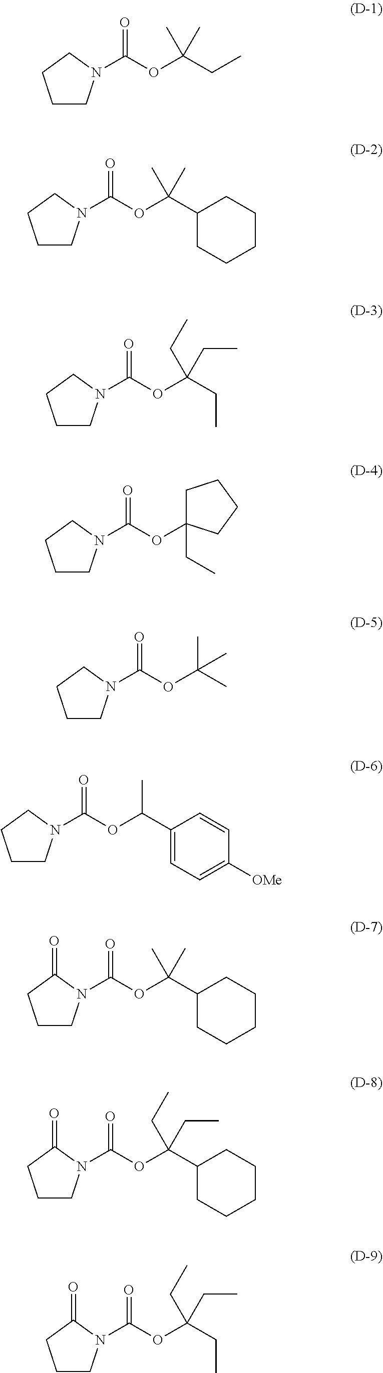

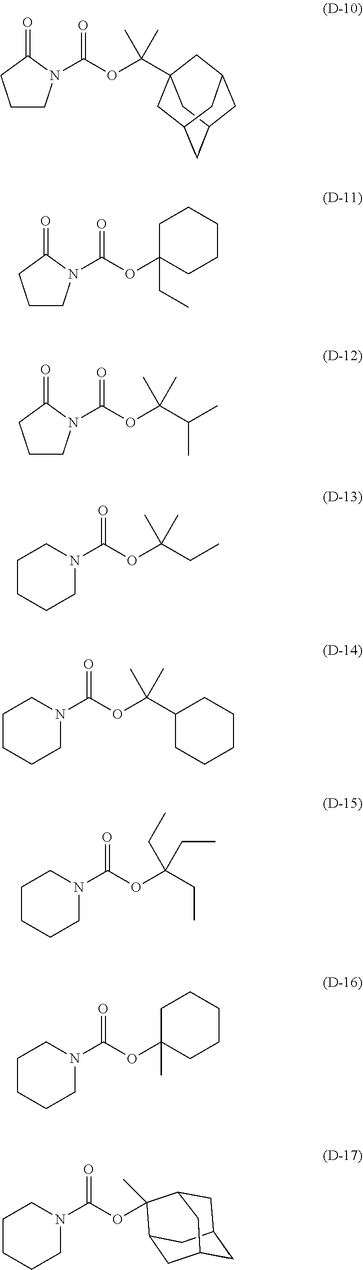

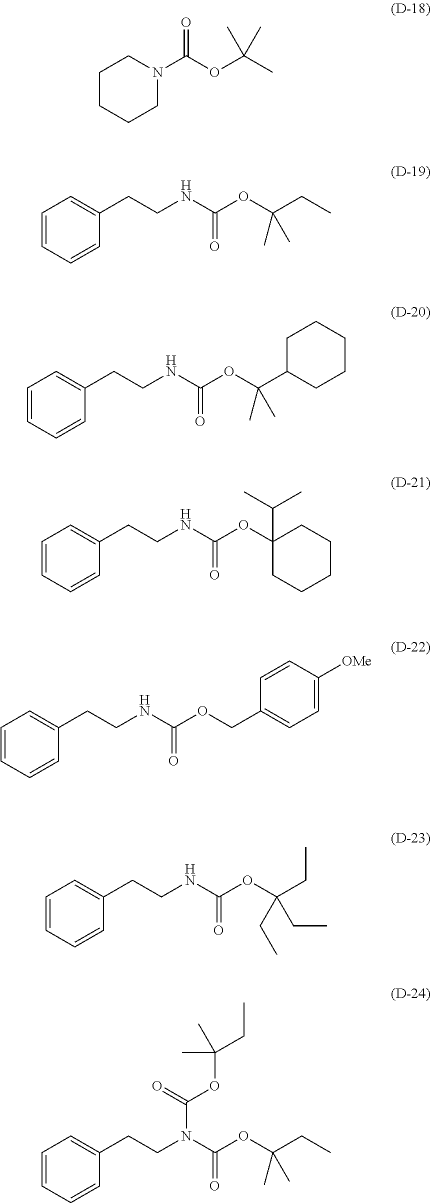

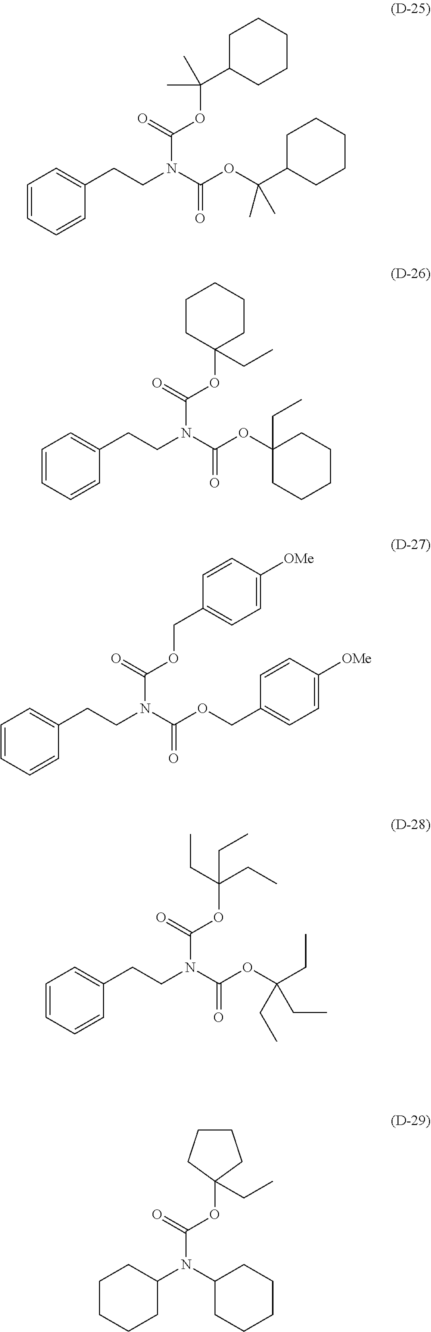 [SMILES: CC(C)(OC(=O)N(CCc1ccccc1)C(=O)OC(C)(C)C1CCCCC1)C1CCCCC1 ; CCC1(OC(=O)N(CCc2ccccc2)C(=O)OC2(CC)CCCCC2)CCCCC1 ; COc1ccc(COC(=O)N(CCc2ccccc2)C(=O)OCc2ccc(OC)cc2)cc1 ; CCC(CC)(CC)OC(=O)N(CCc1ccccc1)C(=O)OC(CC)(CC)CC ; CCC1(OC(=O)N(C2CCCCC2)C2CCCCC2)CCCC1]

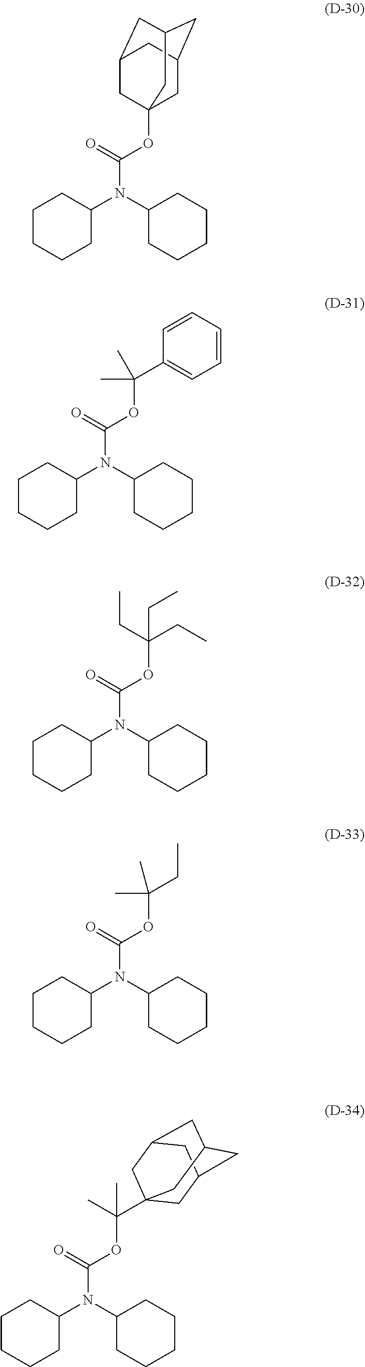 [SMILES: O=C(OC12CC3CC(CC(C3)C1)C2)N(C1CCCCC1)C1CCCCC1 ; CC(C)(OC(=O)N(C1CCCCC1)C1CCCCC1)c1ccccc1 ; CCC(CC)(CC)OC(=O)N(C1CCCCC1)C1CCCCC1 ; CCC(C)(C)OC(=O)N(C1CCCCC1)C1CCCCC1 ; CC(C)(OC(=O)N(C1CCCCC1)C1CCCCC1)C12CC3CC(CC(C3)C1)C2]

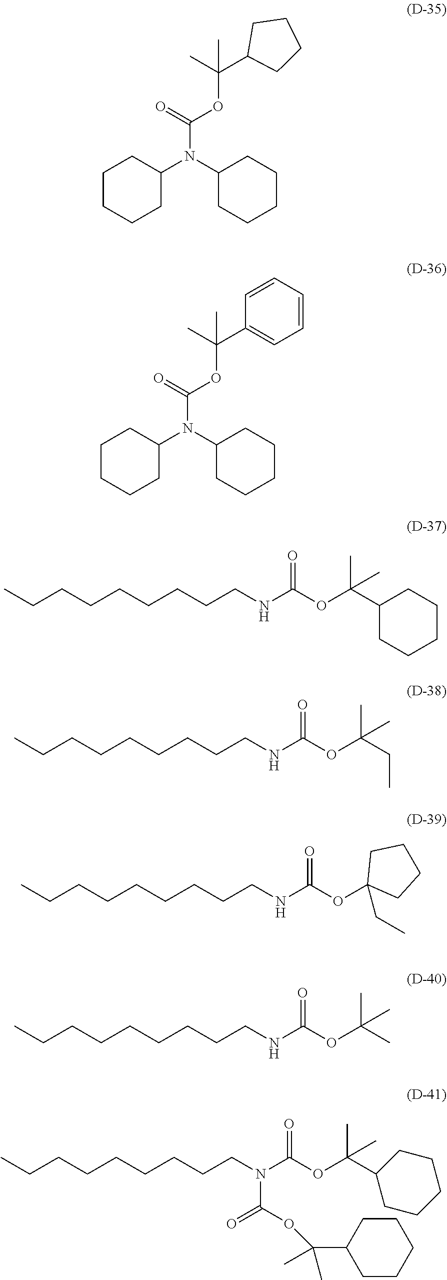

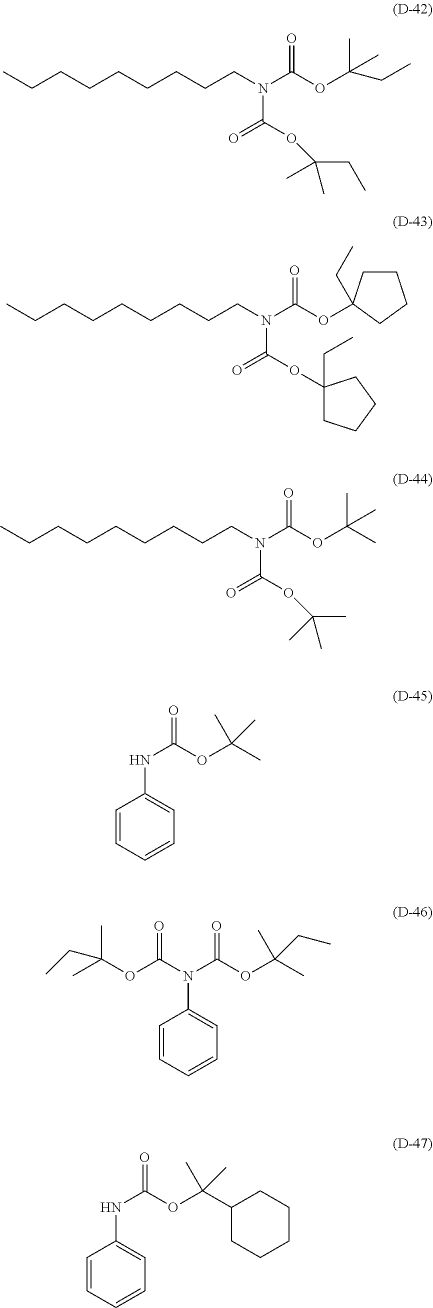

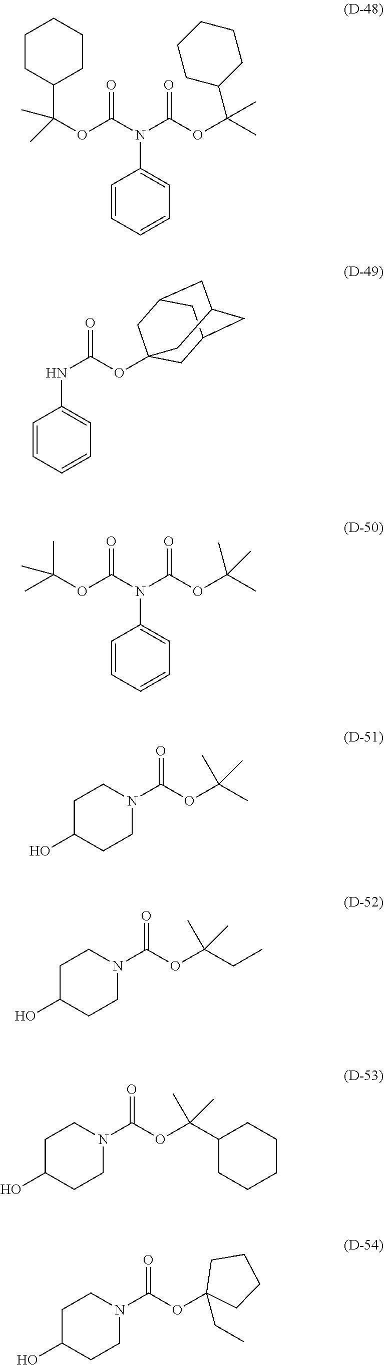

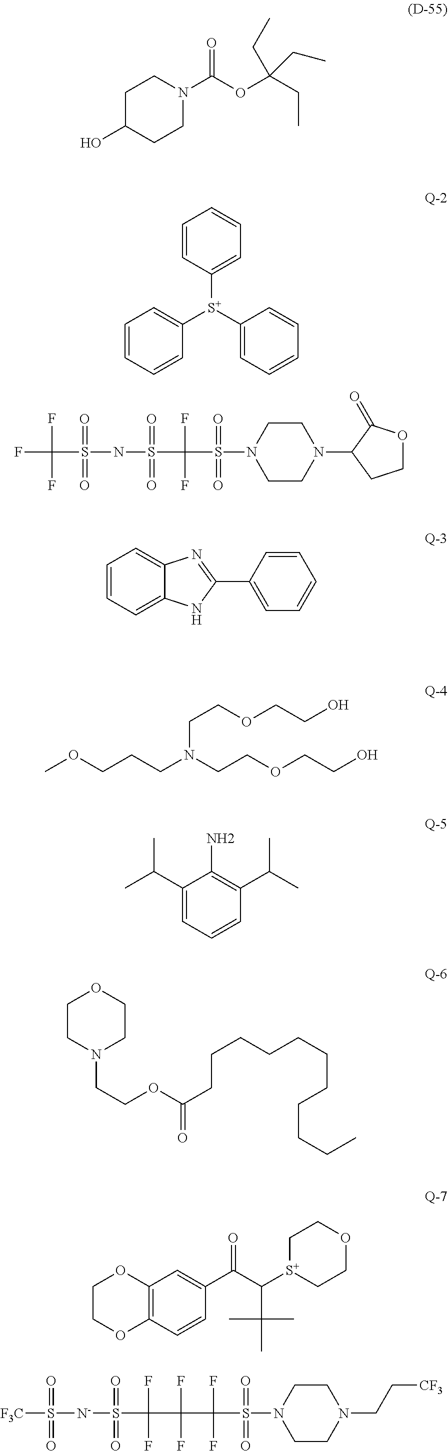

The content of the basic compound in the composition of the embodiment of the present invention is not particularly limited, but is preferably 0.001% to 10% by mass, and more preferably 0.01% to 7% by mass, with respect to the total solid content of the composition.

In addition, the basic compounds may be used alone or in combination of two or more kinds thereof.

(Surfactant)

The composition of the embodiment of the present invention may further include a surfactant, and preferably includes either any one or two or more of fluorine-based and/or silicon-based surfactants (a fluorine-based surfactant, a silicon-based surfactant, or a surfactant having both a fluorine atom and a silicon atom).

By incorporating the surfactant into the composition of the embodiment of the present invention, it becomes possible to form a pattern which has excellent adhesiveness and decreased development defects with good sensitivity and resolution at the time of using an exposure light source of 250 nm or less, and particularly 220 nm or less.

Specific aspects of the surfactant are described in paragraphs 0257 to 0262 of Document A, the contents of which are herein incorporated by reference.

The content of the surfactant in the composition of the embodiment of the present invention is not particularly limited, but is preferably 0.0001% to 2% by mass, and more preferably 0.001% to 1% by mass, with respect to the total solid content of the composition.

In addition, the surfactants may be used alone or in combination of a plurality thereof.

(Onium Carboxylate Salt)

The composition of the embodiment of the present invention may include an onium carboxylate salt.

Examples of the onium carboxylate salt include a sulfonium carboxylate salt, an iodonium carboxylate salt, and an ammonium carboxylate salt. In particular, as the onium carboxylate salt, an iodonium salt or a sulfonium salt is preferable. Furthermore, it is preferable that the carboxylate residue of the onium carboxylate salt does not include an aromatic group or a carbon-carbon double bond. As the anion moiety, a linear or branched, monocyclic or polycyclic alkylcarboxylate anion having 1 to 30 carbon atoms is preferable.

(Dissolution Inhibiting Compound Having Molecular Weight of 3,000 or Less, Whose Solubility in Alkali Developer Increases Through Decomposition by Action of Acid)

The composition of the embodiment of the present invention may include a dissolution inhibiting compound having a molecular weight of 3,000 or less, whose solubility in an alkali developer increases through decomposition by the action of an acid (hereinafter also referred to as a “dissolution inhibiting compound”). As the dissolution inhibiting compound, an alicyclic or aliphatic compound including an acid-decomposable group, such as a cholic acid derivative including an acid-decomposable group described in Proceeding of SPIE, 2724, 355 (1996), so as not to reduce the transparency to light at 220 nm or less.

Incidentally, specific examples of the dissolution inhibiting compound include the compounds described in paragraph 0270 of Document A, the contents of which are herein incorporated by reference.

(Other Additives)

The composition of the embodiment of the present invention may further include a dye, a plasticizer, a photosensitizer, a light absorber, and a compound that accelerates a solubility in a developer (for example, a phenol compound having a molecular weight of 1,000 or less and an alicyclic or aliphatic compound having a carboxyl group), as desired.

<Pattern Forming Method>

The pattern forming method of an embodiment of the present invention includes the following steps (A) to (C).

(A) Resist film forming step: Step of forming a resist film (actinic ray-sensitive or radiation-sensitive resin composition film) on a substrate using an actinic ray-sensitive or radiation-sensitive resin composition.

(B) Exposing step: Step of irradiating the resist film with actinic rays or radiation.

(C) Developing step: Step of developing the resist film irradiated with actinic rays or radiation using an alkali developer.

The pattern forming method may include a step other than the steps. Hereinafter, aspects of the respective steps will be described.

(Resist Film Forming Step)

The resist film forming step is a step of forming a resist film (actinic ray-sensitive or radiation-sensitive resin composition film) on a substrate using an actinic ray-sensitive or radiation-sensitive resin composition actinic ray-sensitive or radiation-sensitive resin composition.

Examples of a method for forming the resist film on the substrate include a method in which an actinic ray-sensitive or radiation-sensitive resin composition is applied onto a substrate. The application method is not particularly limited, and examples thereof include a spin coating method, a spray method, a roller coating method, and a dip method, which is known in the related art, with the spin coating method being preferable.

After forming the resist film, the substrate may be heated (prebaked (PB)), as desired. Thus, a film from which unnecessary residual solvents have been removed can be formed. A prebaking temperature after forming the resist film is not particularly limited, but is preferably 50° C. to 160° C., and more preferably 60° C. to 140° C.

The type of the substrate is not particularly limited, and examples thereof include inorganic substrates such as silicon, SiN, and SiO₂: coating type inorganic substrates such as spin on glass (SOG); and substrates generally used in a process for manufacturing a semiconductor such as an integrated circuit (IC), a process for manufacturing a circuit board for a liquid crystal, a thermal head, or the like, and other lithographic processes of photofabrication, and the like.

The film thickness of the resist film is not particularly limited, but is preferably 100 nm or less.

Prior to forming the resist film, an antireflection film may be disposed onto the substrate in advance.

As the antireflection film, any type of an inorganic film type such as titanium, titanium dioxide, titanium nitride, chromium oxide, carbon, and amorphous silicon, and an organic film type formed of a light absorber and a polymer material can be used. In addition, as the organic antireflection film, a commercially available organic antireflection film such as DUV-30 series or DUV-40 series manufactured by Brewer Science, Inc., AR-2, AR-3, or AR-5 manufactured by Shipley Company, L.L.C., or ARC series such as ARC29A manufactured by Nissan Chemical Industries, Ltd. can also be used.

(Exposing Step)

The exposing step is a step of irradiating the resist film with actinic rays or radiation. The exposure can be performed by a known method, and for example, the resist film is passed through a predetermined mask to be irradiated with actinic rays or radiation. Here, preferably, the actinic rays or radiation is irradiated through an immersion liquid, which is not limitative. An exposure dose can be appropriately selected, but is preferably 10 to 60 mJ/cm².

The wavelength of the light source used for an exposure apparatus is not particularly limited, but light at a wavelength of 250 nm or less is preferable. Examples of the light include KrF excimer laser light (248 nm), ArF excimer laser light (193 nm), F₂ excimer laser light (157 nm), EUV light (13.5 nm), and electron beams. Among these, the ArF excimer laser light (193 nm) is more preferable.

In the case of performing liquid immersion exposure, the surface of the resist film may be washed with an aqueous chemical solution before the exposure and/or after the exposure and before performing heating.

The immersion liquid is preferably a liquid which is transparent to the exposure wavelength and has as small a temperature coefficient of a refractive index as possible so as to minimize the distortion of an optical image projected on the resist film. Particularly, in view of easy availability and easy handleability, water is preferable.

In the case of using water as the immersion liquid, an additive (liquid) that decreases the surface tension of water while increasing the surface-active activity may be added to water at a small ratio. This additive is preferably an additive that does not dissolve the resist film on the substrate and gives only a negligible effect on the optical coat at the undersurface of the lens element. The water to be used is preferably distilled water. Furthermore, pure water obtained by performing filtration through an ion exchange filter or the like may also be used. With these, it is possible to suppress an optical image projected on the resist film from distortion due to incorporation of impurities.

Moreover, in view that the refractive index can be further enhanced, a medium having a refractive index of 1.5 or more can also be used. This medium may be either an aqueous solution or an organic solvent.

In the present invention, it is possible to subject the resist film to liquid immersion exposure at a scanning speed of 700 mm/sec or more. Among those, it is preferable to subject the resist film to liquid immersion exposure at a scanning speed of 800 mm/sec or more.

In the pattern forming method, the exposing step may be performed a plurality of times. In this case, the exposure performed a plurality of times may use the same light source or different light sources, but an ArF excimer laser light (wavelength: 193 nm) is preferably used for the first exposure.

After the exposure, heating (baking) and development are preferably performed, whereby a good pattern can be obtained. The baking temperature is not particularly limited as long as a good pattern is obtained, and is usually 40° C. to 160° C. The baking may be performed once or a plurality of times.

(Developing Step)

The developing step is a step of developing the resist film irradiated with actinic rays or radiation using an alkali developer.

Water is usually included as a solvent in the alkali developer.

Furthermore, alkali components are included in the alkali developer. Examples of the alkali developer include aqueous alkali solutions including inorganic alkalis such as sodium hydroxide, potassium hydroxide, sodium carbonate, sodium silicate, sodium metasilicate, and aqueous ammonia; primary amines such as ethylamine and n-propylamine; secondary amines such as diethylamine and di-n-butylamine; tertiary amines such as triethylamine and methyldiethylamine; alcoholamines such as dimethylethanolamine and triethanolamine; quaternary ammonium salts such as tetramethylammonium hydroxide and tetraethylammonium hydroxide; and cyclic amines such as pyrrole and piperidine.

In addition, the alkali developer can be used after adding an appropriate amount of alcohols and/or a surfactant thereto.

The alkali concentration of the alkali developer is usually 0.1% to 20% by mass.

The pH of the alkali developer is usually 10.0 to 15.0.

After performing a developing treatment using the alkali developer, a rinsing treatment may be carried out using a rinsing liquid, as desired.

Examples of the rinsing liquid include pure water. In addition, an appropriate amount of a surfactant may be added to the rinsing liquid.

Moreover, after the developing treatment or the rinsing treatment, a treatment for removing the developer or rinsing liquid adhering on the pattern by a supercritical fluid may be performed.

The pattern forming method can be applied to a method for manufacturing an electronic device. In the present specification, the electronic device is intended to mean a semiconductor device, a liquid crystal device, and electric or electronic equipment (home appliances, media-related equipment, optical equipment, telecommunication equipment, and the like).

### Examples

Hereinbelow, the present invention will be described in more detail with reference to Examples. The materials, the amounts of materials used, the proportions, the treatment details, the treatment procedure, and the like shown in Examples below may be modified, as appropriate, as long as the modifications do not depart from the spirit of the present invention. Therefore, the scope of the present invention should not be construed as being limited to Examples shown below.

(Resin A (Acid-Decomposable Resin))

The structures of the structures of the resins A used Examples are shown below. Furthermore, the molar ratios of repeating units (corresponding to repeating units starting from the left in the structural formulae), the weight-average molecular weight (Mw), and the molecular weight distribution (Pd=Mw/Mn) in each of the resins are shown in Table 1.

TABLE 1

| Type | Compositional ratio | Mw | Pd |
|---|---|---|---|
| A-1 | 45/10/25/20 | 14,000 | 1.5 |
| A-2 | 40/60 | 15,000 | 1.7 |
| A-3 | 40/60 | 7,000 | 1.8 |
| A-4 | 40/50/10 | 15,000 | 2.2 |
| A-5 | 30/10/60 | 7,000 | 1.6 |
| A-6 | 30/10/60 | 6,000 | 2 |
| A-7 | 55/5/35/5 | 20,000 | 1.8 |
| A-8 | 25/5/50/20 | 20,000 | 1.7 |
| A-9 | 40/60 | 20,000 | 1.6 |

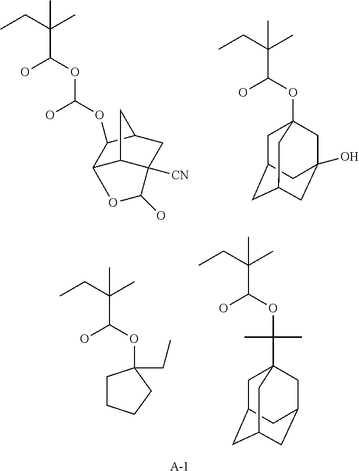

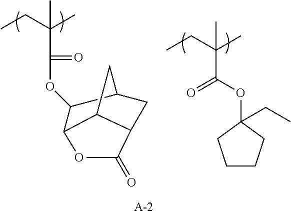

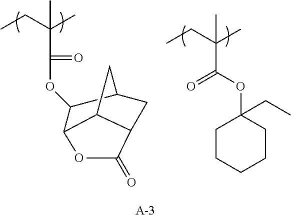

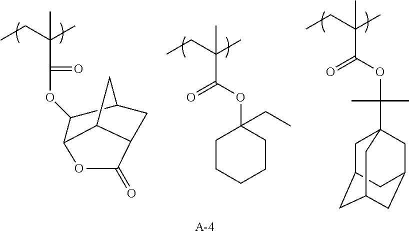

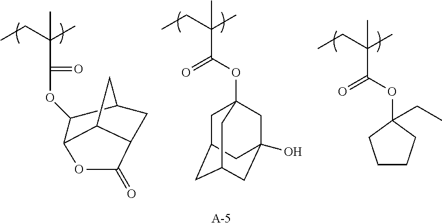

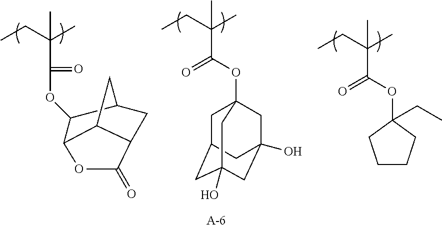

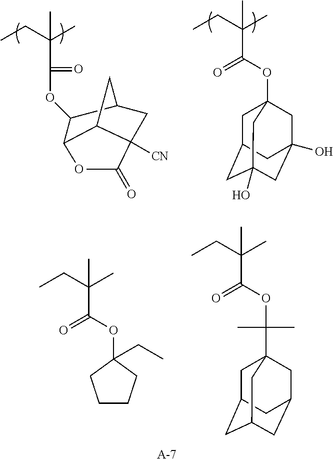

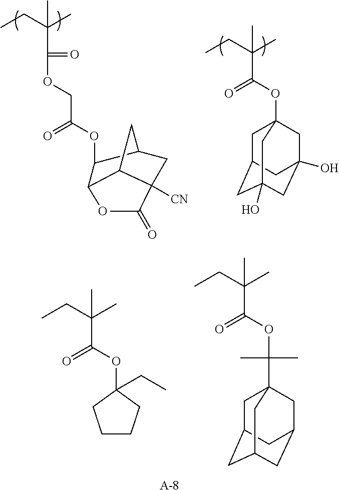

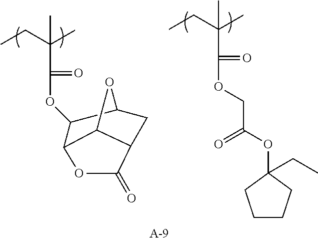

(Acid Generator B)

The acid generators B used in Example are shown below.

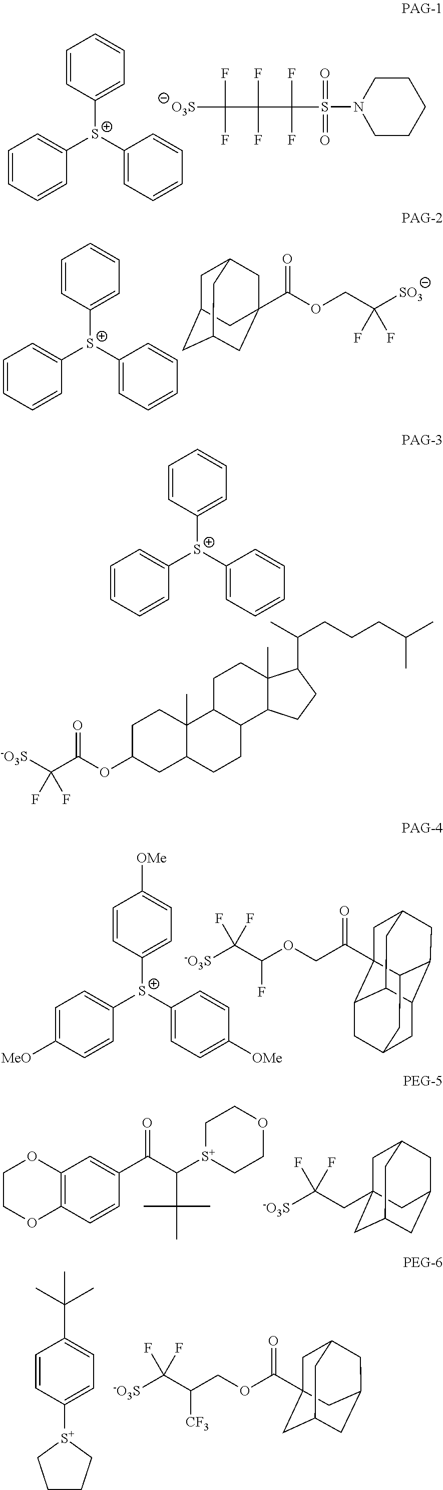

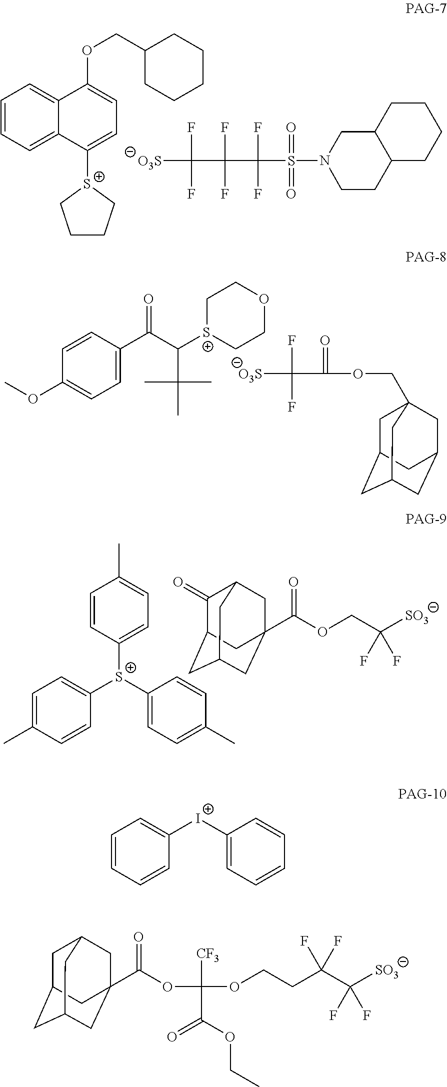

(Resin C)

The structures of the resins C used in Examples are shown below. Furthermore, the molar ratios of repeating units (corresponding to repeating units starting from the left in the structural formulae), the weight-average molecular weight (Mw), and the molecular weight distribution (Pd=Mw/Mn) in each of the resins are shown in Table 2.

TABLE 2

| Resin C | Compositional ratio | Mw | Pd |
|---|---|---|---|
| C-1 | 90/8/2 | 5,500 | 1.2 |
| C-2 | 100 | 12,000 | 1.6 |
| C-3 | 100 | 8,000 | 1.5 |

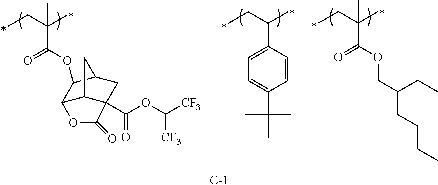

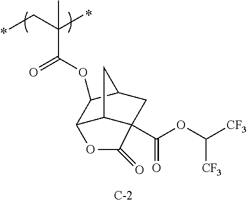

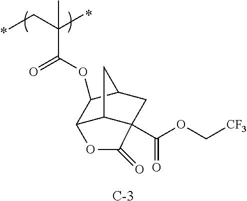

(Resin D)

The structures of the resins D used in Examples are shown below. Furthermore, the molar ratios of repeating units (corresponding to repeating units starting from the left in the structural formulae), the weight-average molecular weight (Mw), and the molecular weight distribution (Pd=Mw/Mn) in each of the resins are shown in Table 3.

TABLE 3

| Resin D | Compositional ratio | Mw | Pd |
|---|---|---|---|
| D-1 | 96/2/2 | 18,000 | 1.3 |
| D-2 | 100 | 7,000 | 1.6 |
| D-3 | 10/90 | 8,000 | 1.5 |
| D-4 | 95/5 | 21,000 | 1.2 |
| D-5 | 5/95 | 8,400 | 1.3 |
| D-6 | 5/95 | 22,000 | 1.6 |
| D-7 | 95/5 | 8,000 | 1.4 |
| D-8 | 10/5/85 | 30,000 | 1.5 |
| D-9 | 90/10 | 19,000 | 1.3 |
| D-10 | 80/20 | 22,000 | 14 |
| D-11 | 50/50 | 7,600 | 1.8 |
| D-12 | 50/50 | 8,500 | 1.8 |
| D-13 | 37/59/2/2 | 5,500 | 1.2 |

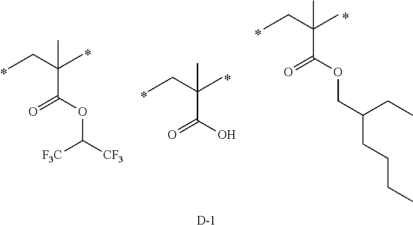

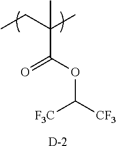

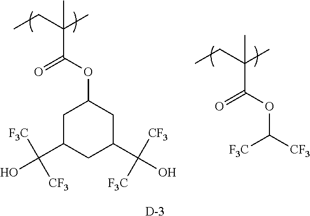

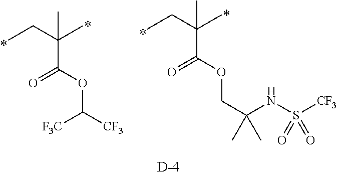

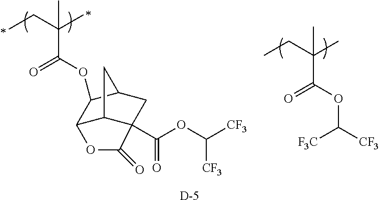

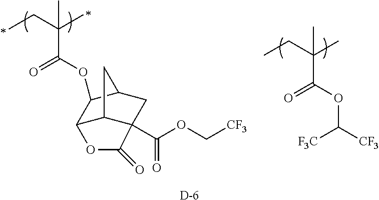

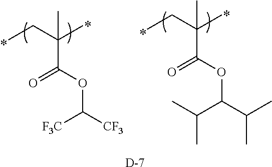

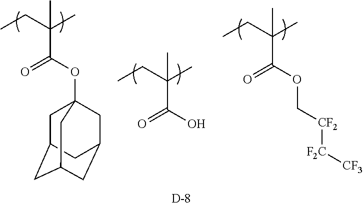

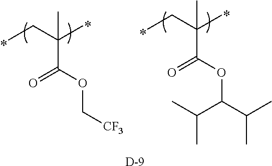

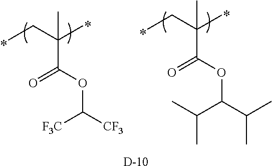

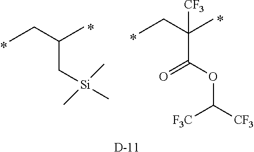

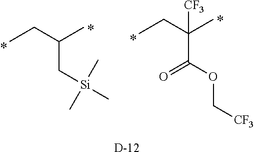

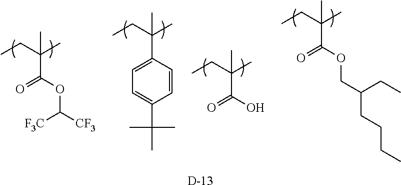

(Basic Compound)

The basic compounds used in Examples are shown below.

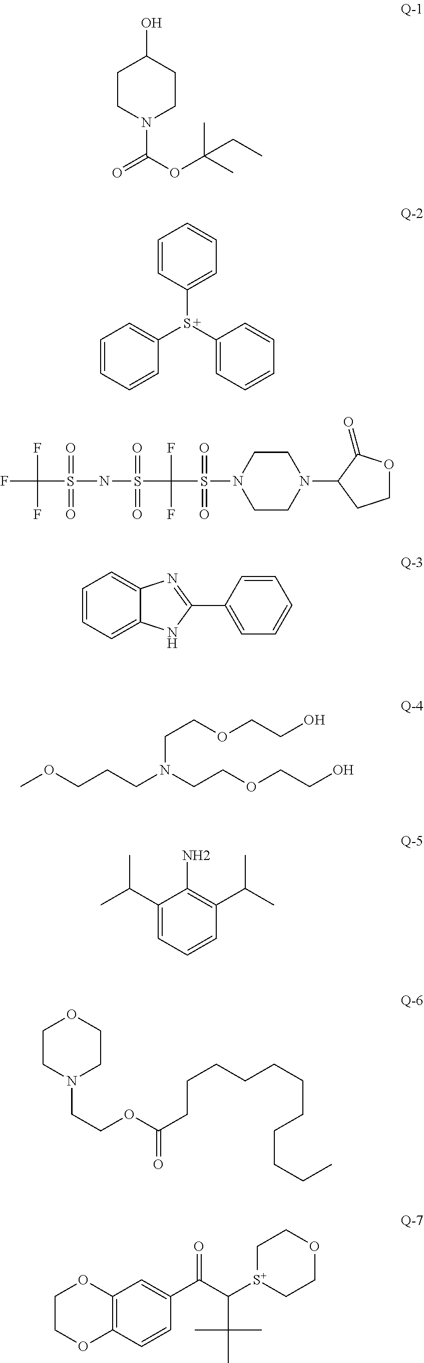

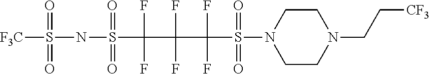 [SMILES: O=S(=O)(NS(=O)(=O)C(F)(F)C(F)(F)C(F)(F)S(=O)(=O)N1CCN(CCC(F)(F)F)CC1)C(F)(F)F]

(Solvent)

The solvents used in Examples are shown below

SL-1: Propylene glycol monomethyl ether acetate (PGMEA) (boiling point: 146° C.)

SL-2: γ-Butyrolactone (boiling point: 204° C.)

SL-3: Cyclohexanone (boiling point: 155° C.)

SL-4: Propylene glycol monomethyl ether (PGME) (boiling point: 120° C.)

SL-5: n-Decane (boiling point: 174° C.)

(Preparation of Actinic Ray-Sensitive or Radiation-Sensitive Resin Composition)

The components shown in Table 4 below were dissolved in a solvent to prepare a solution at a concentration of the solid content of 4.2% by mass. The solution was filtered over a polyethylene filter having a pore size of 0.03 microns to prepare an actinic ray-sensitive or radiation-sensitive resin composition (resist composition).

In addition, the “Mass ratio” in the Solvent section in Table 4 is intended to mean a mass ratio of two solvents used.

TABLE 4

| | | Resin A | | Acid generator B | | Resin C | | Resin D | |
|---|---|---|---|---|---|---|---|---|---|
| | Type of | | Mass | | Mass | | Mass | | Mass |
| | composition | Type | proportion | Type | proportion | Type | proportion | Type | proportion |
| Example 1 | Resist-1 | A-1 | 82.2 | PAG-1 | 9.0 | C-1 | 2.0 | D-1 | 1.2 |
| Example 2 | Resist-2 | A-2 | 82.2 | PAG-2 | 9.0 | C-1 | 2.0 | D-2 | 1.2 |
| Example 3 | Resist-3 | A-3 | 82.2 | PAG-3 | 9.0 | C-2 | 2.0 | D-2 | 1.2 |
| Example 4 | Resist-4 | A-4 | 81.9 | PAG-4 | 9.0 | C-1 | 2.0 | D-3 | 1.5 |
| Example 5 | Resist-5 | A-5 | 82.1 | PAG-2/ | 4.5/4.5 | C-1 | 2.0 | D-4 | 1.3 |
| | | | | PAG-5 | | | | | |
| Example 6 | Resist-6 | A-6 | 82.1 | PAG-6 | 9.0 | C-1 | 2.0 | D-5 | 1.3 |
| Example 7 | Resist-7 | A-7 | 82.1 | PAG-1/ | 4.5/4.5 | C-1 | 2.0 | D-6 | 1.3 |
| | | | | PAG-7 | | | | | |
| Example 8 | Resist-8 | A-8 | 82.2 | PAG-8 | 9.0 | C-1 | 2.0 | D-7 | 1.2 |
| Example 9 | Resist-9 | A-9 | 82.1 | PAG-9 | 9.0 | C-1 | 2.0 | D-8 | 1.3 |
| Example 10 | Resist-10 | A-1 | 81.9 | PAG-10 | 9.0 | C-1 | 2.0 | D-9 | 1.5 |
| Example 11 | Resist-11 | A-1 | 81.9 | PAG-1 | 9.0 | C-1 | 2.0 | D-10 | 1.5 |
| Example 12 | Resist-12 | A-1 | 82.2 | PAG-2 | 9.0 | C-1 | 2.0 | D-11 | 1.2 |
| Example 13 | Resist-13 | A-1 | 82.0 | PAG-1 | 9.0 | C-1 | 2.0 | D-12 | 1.4 |
| Example 14 | Resist-14 | A-1 | 82.2 | PAG-2 | 9.0 | C-3 | 2.0 | D-1 | 1.2 |
| Example 15 | Resist-15 | A-1 | 82.2 | PAG-1 | 9.0 | C-1 | 2.0 | D-1 | 1.2 |
| Example 16 | Resist-16 | A-1 | 82.2 | PAG-1 | 9.0 | C-1 | 2.0 | D-1 | 1.2 |
| Example 17 | Resist-17 | A-1 | 82.2 | PAG-1 | 9.0 | C-1 | 2.0 | D-1 | 1.2 |
| Comparative | Resist-18 | A-1 | 83.4 | PAG-1 | 9.0 | C-1 | 2.0 | — | — |
| Example 1 | | | | | | | | | |
| Comparative | Resist-19 | A-1 | 82.4 | PAG-1 | 9.0 | C-1 | 2.0 | D-1 | 1.0 |
| Example 2 | | | | | | | | | |
| Comparative | Resist-20 | A-1 | 82.2 | PAG-1 | 9.0 | C-1 | 2.0 | D-13 | 1.2 |
| Example 3 | | | | | | | | | |
| | | Basic compound | | | | Solvent | | | |
| | | | Mass | | Mass | | Mass | | Mass |
| | | Type | proportion | Type | proportion | Type | ratio | Type | ratio |
| | Example 1 | Q-1 | 0.1 | Q-2 | 5.5 | SL-1 | 97 | SL-2 | 3 |
| | Example 2 | Q-3 | 5.6 | | | SL-1 | 97 | SL-2 | 3 |
| | Example 3 | Q-4 | 5.6 | | | SL-1 | 97 | SL-2 | 3 |
| | Example 4 | Q-4 | 5.6 | | | SL-1 | 97 | SL-2 | 3 |
| | Example 5 | Q-1 | 0.1 | Q-7 | 5.5 | SL-1 | 97 | SL-2 | 3 |
| | Example 6 | Q-5 | 5.6 | | | SL-1 | 97 | SL-2 | 3 |
| | Example 7 | Q-6 | 5.6 | | | SL-1 | 97 | SL-2 | 3 |
| | Example 8 | Q-1 | 0.1 | Q-7 | 5.5 | SL-1 | 97 | SL-2 | 3 |
| | Example 9 | Q-1 | 5.6 | | | SL-1 | 97 | SL-2 | 3 |
| | Example 10 | Q-1 | 0.1 | Q-2 | 5.5 | SL-1 | 97 | SL-2 | 3 |
| | Example 11 | Q-3 | 5.6 | | | SL-1 | 97 | SL-2 | 3 |
| | Example 12 | Q-4 | 5.6 | | | SL-1 | 97 | SL-2 | 3 |
| | Example 13 | Q-1 | 5.6 | | | SL-1 | 97 | SL-2 | 3 |
| | Example 14 | Q-2 | 5.6 | | | SL-1 | 97 | SL-2 | 3 |
| | Example 15 | Q-1 | 0.1 | Q-2 | 5.5 | SL-1 | 97 | SL-3 | 3 |
| | Example 16 | Q-1 | 0.1 | Q-2 | 5.5 | SL-1 | 97 | SL-4 | 3 |
| | Example 17 | Q-1 | 0.1 | Q-2 | 5.5 | SL-1 | 97 | SL-5 | 3 |
| | Comparative | Q-1 | 0 1 | Q-2 | 5.5 | SL-1 | 97 | SL-2 | 3 |
| | Example 1 | | | | | | | | |
| | Comparative | Q-1 | 0.1 | Q-2 | 5.5 | SL-1 | 97 | SL-2 | 3 |
| | Example 2 | | | | | | | | |
| | Comparative | Q-1 | 0.1 | Q-2 | 5.5 | SL-1 | 97 | SL-2 | 3 |
| | Example 3 | | | | | | | | |

A composition for forming an organic antireflection film, ARC29A (manufactured by Nissan Chemical Industries, Ltd.), was applied onto a silicon wafer and baked at 205° C. for 60 seconds to form an antireflection film having a film thickness of 86 nm.

The prepared actinic ray-sensitive or radiation-sensitive resin composition was applied on the antireflection film thus formed, and the coating film was baked at 130° C. over 60 seconds to form a resist film having a film thickness of 90 nm. A wafer with the obtained resist film was exposed through a 6% halftone mask having a 1:1 line-and-space pattern with a width of 75 nm, using an ArF excimer laser liquid immersion scanner (PAS5500/1100 manufactured by ASML, NA 0.75). Ultrapure water was used as the immersion liquid. Thereafter, the resist film which has been subjected to the exposing treatment was heated at 95° C. for 60 seconds, developed with an aqueous tetramethylammonium hydroxide solution (2.38% by mass) for 30 seconds, rinsed with pure water, and then spin-dried to obtain a pattern.

(LWR Evaluation)

The line pattern finished to a dimension of 75 nm in the procedure above was observed with a scanning microscope (δ9260 manufactured by Hitachi Ltd.), and with respect to a range with a 2-μm edge in the longitudinal direction of the line pattern, a distance from a reference line where the edge should be present was measured at 50 points and a standard deviation was determined to calculate 3σ. A smaller value thereof indicates better performance.

(Evaluation of Dynamic Receding Contact Angle)

The prepared actinic ray-sensitive or radiation-sensitive resin composition was spin-applied onto a silicon wafer and then the coating film was baked on a hot plate to form a resist film having a film thickness of 90 nm.

Subsequently, the wafer was installed on a wafer stage of a contact angle meter. In the state where liquid droplets of pure water were ejected from a syringe and kept as they were, the liquid droplets were brought into contact with the resist film. Then, while fixing the syringe, the wafer stage was allowed to move at a speed of 250 mm/sec. The receding angles of the liquid droplets during the stage movement were measured and a value at which the contact angle was stabilized was defined as a dynamic receding angle.

In addition, measurement of the contact angle was carried out at room temperature 23° ° C.±3° C.

(Evaluation of Post-Development Contact Angle)

The prepared actinic ray-sensitive or radiation-sensitive resin composition was spin-applied onto a silicon wafer and then the coating film was baked on a hot plate to form a resist film having a film thickness of 90 nm.

Subsequently, the resist film was developed with an aqueous tetramethylammonium hydroxide solution (2.38% by mass) for 30 seconds, rinsed with pure water, and then spin-dried.

Thereafter, the static contact angle (0) of the water droplet on the surface of the obtained resist film was measured using a contact angle meter (manufactured by Kyowa Interface Science Co., Ltd.). The static contact angle was measured with a liquid droplet size of 35 μL at room temperature 23° C.±3° C. and a humidity of 45%±5%, and a value at which the contact angle was stabilized was defined as a post-development contact angle. A larger value thereof indicates higher hydrophilicity of the resist film after being in contact with the alkali developer and better wetting extendability of the alkali developer.

(Evaluation of Surface Energy)

Each of the resins C shown in Table 2 was dissolved in propylene glycol monomethyl ether acetate to prepare a solution at a concentration of the solid content of 4.0% by mass.

The prepared solution was spin-applied onto a silicon wafer and then the coating film was baked on a hot plate to form a film having a film thickness of 90 nm. Thereafter, the static contact angles (°) of pure water and diiodomethane were measured using a contact angle meter (manufactured by Kyowa Interface Science Co., Ltd.). The static contact angles were measured with a liquid droplet size of 35 μL at room temperature 23° C.±3° C. and a humidity of 45%±5%, and a value at which the contact angle was stabilized was defined as a static contact angle. The surface energy of the film was measured by an Owens-Wendt method using the static contact angle of water and the static contact angle of diiodomethane thus obtained, and was defined as the surface energy of each of the resins C.

In addition, the surface energy of each of the resins D was calculated according to the same procedure, using the resin D shown in Table 3 instead of the resin C.

TABLE 5

| | | | | Dynamic | | |
|---|---|---|---|---|---|---|
| | Type of | Surface energy | Surface energy | receding contact | Post-development | LWR |
| | composition | (mJ/m²) of resin C | (mJ/m²) of resin D | angle (°) | contact angle (°) | (nm) |
| Example 1 | Resist-1 | 33 | 20 | 83 | 76 | 8.2 |
| Example 2 | Resist-2 | 33 | 19 | 84 | 78 | 8.1 |
| Example 3 | Resist-3 | 35 | 19 | 84 | 77 | 8.1 |
| Example 4 | Resist-4 | 33 | 22 | 82 | 74 | 8.6 |
| Example 5 | Resist-5 | 33 | 23 | 81 | 75 | 8.8 |
| Example 6 | Resist-6 | 33 | 22 | 83 | 74 | 8.2 |
| Example 7 | Resist-7 | 33 | 23 | 81 | 74 | 8.3 |
| Example 8 | Resist-8 | 33 | 21 | 86 | 77 | 8.0 |
| Example 9 | Resist-9 | 33 | 22 | 82 | 79 | 8.8 |
| Example 10 | Resist-10 | 33 | 22 | 80 | 72 | 8.1 |
| Example 11 | Resist-11 | 33 | 21 | 82 | 76 | 8.2 |
| Example 12 | Resist-12 | 33 | 19 | 86 | 74 | 7.3 |
| Example 13 | Resist-13 | 33 | 21 | 83 | 72 | 7.6 |
| Example 14 | Resist-14 | 37 | 20 | 80 | 72 | 8.3 |
| Example 15 | Resist-15 | 33 | 20 | 83 | 75 | 8.2 |
| Example 16 | Resist-16 | 33 | 20 | 80 | 76 | 8.3 |
| Example 17 | Resist-17 | 33 | 20 | 83 | 74 | 8.3 |
| Comparative | Resist-18 | 33 | — | 71 | 45 | 8.2 |
| Example 1 | | | | | | |
| Comparative | Resist-19 | 33 | 20 | 77 | 68 | 8.0 |
| Example 2 | | | | | | |
| Comparative | Resist-20 | 33 | 31 | 85 | 80 | 9.5 |
| Example 3 | | | | | | |

As shown in Table 5, it was found that desired effects were obtained by use of the composition of the embodiment of the present invention.

On the other hand, in Comparative Example 1 in which the resin D was not used, Comparative Example 2 in which the content of the resin D was less than 1.1% by mass, and Comparative Example 3 in which the surface energy of the resin D was more than 25 mJ/m², desired effects were not obtained.

What is claimed is:

1. An actinic ray-sensitive or radiation-sensitive resin composition comprising:
a resin A whose solubility in an alkali developer increases by the action of an acid;
a compound B that generates an acid upon irradiation with actinic rays or radiation;
a resin C that has a surface energy of more than 25 mJ/m², has at least one of a fluorine atom or a silicon atom, and has a polarity conversion group; and
a resin D that has a surface energy of 25 mJ/m² or less,
wherein a content of the resin D is 1.1% by mass or more with respect to the total solid content of the actinic ray-sensitive or radiation-sensitive resin composition.

2. The actinic ray-sensitive or radiation-sensitive resin composition according to claim 1, further comprising two or more solvents,
wherein a boiling point of at least one solvent of the solvents is 140° C. or higher.

3. The actinic ray-sensitive or radiation-sensitive resin composition according to claim 2, comprising a first solvent having a boiling point of 140° C. or higher and a second solvent having a higher boiling point than the first solvent.

4. The actinic ray-sensitive or radiation-sensitive resin composition according to claim 1,
wherein the resin C has a repeating unit (c′) having at least one of a fluorine atom or a silicon atom and having a polarity conversion group on one side chain.

5. The actinic ray-sensitive or radiation-sensitive resin composition according to claim 1,
wherein the resin C has a repeating unit having a group represented by General Formula (2), 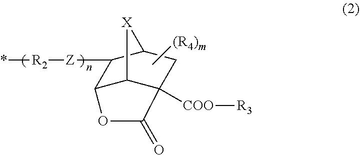
in General Formula (2),
R₂ represents a chained or cyclic alkylene group, and in a case where a plurality of R₂'s are present, R₂'s may be the same as or different from each other,
R₃ represents a linear, branched, or cyclic hydrocarbon group in which the hydrogen atoms are partly or fully substituted with fluorine atoms, and
R₄ represents a halogen atom, a cyano group, a hydroxyl group, an amido group, an alkyl group, a cycloalkyl group, an alkoxy group, a phenyl group, an acyl group, an alkoxycarbonyl group, R—C(═O)—, or a group represented by R—C(═O)O—, R represents an alkyl group or a cycloalkyl group, and in a case where a plurality of R₄'s are present, R₄'s may be the same as or different from each other, and two or more of R₄'s may be bonded to each other to form a ring.

6. The actinic ray-sensitive or radiation-sensitive resin composition according to claim 1,
wherein the resin C has a monovalent or higher group formed by removing at least one of any hydrogen atoms in a partial structure represented by General Formula (KY-2), 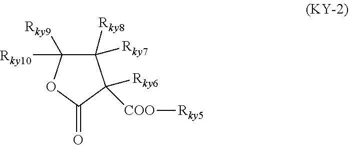
in General Formula (KY-2), R_{ky6} to R_{ky10} each independently represent a hydrogen atom, a halogen atom an alkyl group, a cycloalkyl group, a carbonyl group, a carbonyloxy group, an oxycarbonyl group, an ether group, a hydroxyl group, a cyano group, an amido group, or an aryl group,
two or more of R_{ky6} to R_{ky10} may be linked to each other to form a monocyclic or polycyclic structure, and
R_{ky5} represents an electron-withdrawing group.

7. The actinic ray-sensitive or radiation-sensitive resin composition according to claim 1,
wherein the resin D has at least one of a repeating unit represented by General Formula (C-1a), (C-1b), (C-1c), or (C-1d), 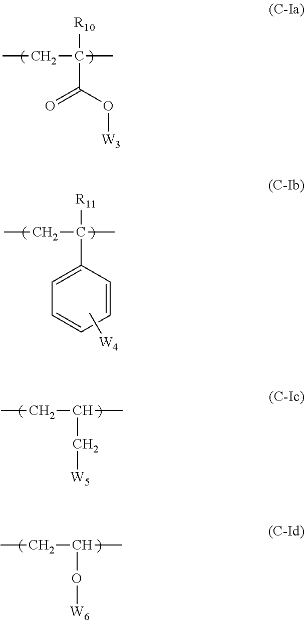
in the formulae, R₁₀ and R₁₁ each independently represent a hydrogen atom, a fluorine atom, or an alkyl group, and
W₃ to W₆ each independently represent an organic group including at least one or more fluorine atoms.

8. The actinic ray-sensitive or radiation-sensitive resin composition according to claim 1,
wherein a mass ratio of the resin D to the resin C is 0.1 or more.

9. The actinic ray-sensitive or radiation-sensitive resin composition according to claim 4,
wherein a mass ratio of the resin D to the resin C is 0.1 or more.

10. The actinic ray-sensitive or radiation-sensitive resin composition according to claim 5,
wherein a mass ratio of the resin D to the resin C is 0.1 or more.

11. The actinic ray-sensitive or radiation-sensitive resin composition according to claim 6,
wherein a mass ratio of the resin D to the resin C is 0.1 or more.

12. The actinic ray-sensitive or radiation-sensitive resin composition according to claim 7,
wherein a mass ratio of the resin D to the resin C is 0.1 or more.

13. A resist film formed using the actinic ray-sensitive or radiation-sensitive resin composition according to claim 1.

14. A pattern forming method comprising:
forming a resist film on a substrate using the actinic ray-sensitive or radiation-sensitive resin composition according to claim 1;
irradiating the resist film with actinic rays or radiation; and
developing the resist film irradiated with actinic rays or radiation using an alkali developer.

15. A method for manufacturing an electronic device, comprising the pattern forming method according to claim 6.
